(19) United States
(12) Patent Application Publication
(10) Pub. No.: US 2016/0133771 A1
(43) Pub. Date: May 12, 2016

(54) TIR CONCENTRATOR OPTICS

(71) Applicant: TIR ENERGY, LLC, PALO ALTO, CA (US)

(72) Inventor: KEVIN M. PELLETIER, GOLD RIVER, CA (US)

(73) Assignee: TIR ENERGY, LLC, PALO ALTO, CA (US)

(21) Appl. No.: 14/535,635

(22) Filed: Nov. 7, 2014

(51) Int. Cl. H01L 31/054; G02B 19/00; G06F 17/50; H02S 40/22

(52) U.S. Cl. CPC H01L 31/0543; H02S 40/22; G02B 19/0028; G02B 19/0042; G06F 17/50

(57) ABSTRACT

The HCPV industry has converged on the use of relatively inexpensive Fresnel refractive optics to concentrate sunlight to 500-1000 suns or more. One fundamental disadvantage of using Fresnel optics is their susceptibility to chromatic aberration. With a Fresnel lens, this chromatic aberration increases as a function of distance away from the optical axis of a lens—that is, greater chromatic aberration is seen as one moves along a radius away from the center of a Fresnel lens. Embodiments herein disclose TIR-mediated optics which can be used alone or with Fresnel-mediated optics to concentrate solar energy. The system and method described herein utilize novel TIR and Fresnel concentrator designs to enable lower F-number optical systems, resulting in smaller systems with higher concentrations of solar energy than is currently attainable with Fresnel lenses alone (or with secondary optics) while simultaneously minimizing chromatic aberration.

### BACKGROUND OF THE INVENTION

1. Field of the Invention

The present invention relates generally to concentrator optics, particularly as used in high concentration photovoltaic systems.

2. Description of the Prior Art

Cost has been a major barrier to widespread adoption of solar power as a renewable energy source for residential and commercial applications. The standard of comparison for any renewable energy technology (including solar energy), is the cost of electricity for coal- or gas-fired power plants. This is a challenging standard since these technologies have been well-developed and entrenched for many years. Although a variety of government subsidies have been used to develop and promote the adoption of new renewable energy sources, renewable energies such as solar technologies must ultimately compete on the basis of cost. For photovoltaic technologies, two primary approaches can be used to reduce the cost of electricity produced. One approach is to reduce the cost of a photovoltaic system while maintaining power output. For example, government subsidies have driven up demand for photovoltaic systems and large volume shipments have enabled companies to realize cost reductions from economies of scale pricing of parts and increased manufacturing efficiency while maintaining a stable power output. A second approach to reduce cost is to increase conversion efficiency of photovoltaic systems so that more power is produced from a given amount of material, thereby reducing the cost of electricity produced. While all energy technologies can benefit from manufacturing cost reductions driven by increased volume, photovoltaic technologies stand out as an energy source which has a capacity for increases in overall system efficiency.

Concentration photovoltaic (“CPV”) systems typically use concentrator optics (such as reflectors or lenses) to collect and focus (i.e., concentrate) sunlight onto solar photovoltaic cells to generate energy. Concentrating sunlight onto a solar cell can increase the efficiency with which a solar cell converts sunlight to electricity. This increased efficiency, in turn, can result in higher electrical energy production per unit area of a solar cell than might be achieved with a non-concentration photovoltaic system. Although adding concentration optics to a photovoltaic system can increase the cost of the system, the cost of energy produced from a CPV system can be lower than the cost of energy for a non-concentration photovoltaic system—as long as the additional cost of the concentration optics is not too high.

A solar cell is typically one of the most expensive components of a photovoltaic system. Light-gathering system components such as reflectors or lens typically cost less per unit area than the solar cell itself. Thus, with an appropriate optical design, a less expensive optical system can be used as the primary surface area to gather sunlight and direct it to a smaller area on the solar cell without sacrificing system energy output per unit area. In such a case, the cost of energy produced from a CPV system would be lower than for a non-concentrated photovoltaic system because smaller and less expensive solar cells can be used with lower cost lens(es) or reflector material(s) while maintaining or increasing system energy output.

Typical CPV systems can concentrate solar energy over a range of 2 to more than 1000 suns. In practice, CPV systems are classified based on the solar cell technology employed: silicon or triple-junction solar cells. As a low band gap material, silicon absorbs most wavelengths in the solar spectrum, so concentrator designs are not complex and use simple materials (e.g., a curved aluminum reflector). The low band gap of silicon solar cells and the degradation of performance resulting from the increased cell temperature experienced under concentrated sunlight, however, results in a practical upper concentration limit of about 100 suns for silicon solar cell-based CPV systems. Thus, low concentration CPV systems typically utilize silicon solar cells with optical concentrations typically lower than 100 suns. In fact, almost all CPV systems using silicon solar cells operate in the range of 2 to 20 sun concentration.

Triple-junction solar cells based on III-V materials (“III-V solar cells”) are an attractive alternative to silicon cells. A triple-junction solar cell typically consists of a germanium (Ge) bottom subcell, an indium gallium arsenide (InGaAs) middle subcell and an indium gallium phosphide (InGaP) top subcell. Because each subcell has a different band gap and very efficiently converts a portion of the solar spectrum to electricity, the efficiency of a triple-junction solar cell is much better than that of a cell made from a single semiconductor such as silicon. The temperature dependence of III-V materials is, however, much lower than silicon, thereby enabling triple-junction solar cells to operate well under high concentrations of sunlight. Under concentration, III-V solar cells have set a series of world record solar cell efficiencies—up to nearly 45% efficiency. By contrast, the best silicon cells operate at about 22% efficiency.

The biggest barrier to the use of triple-junction materials in photovoltaic systems has been the high cost of the solar cells. While III-V solar cells have been used for many years in space satellite applications, the cost of multi-junction solar cells in dollars per cm² is 10-100 times higher than for silicon solar cells. Thus, even the higher efficiency of a multi-junction solar cell cannot offset its higher material cost enough to be cost effective in unconcentrated or low concentration applications.

If high concentration optics are used to gather and focus sunlight onto a triple-junction solar cell, however, solar concentration can be increased to 500 suns or more. In such high concentration photovoltaic (“HCPV”) systems, the light-gathering area of a solar module can be made of inexpensive materials (e.g., silicone, glass, PMMA) and the actual semiconductor area of a can be reduced to 1/500 ^{th}, or 1/1000^{th}, or 1/2000^{th} of the area of a comparable energy module using silicon cells—while simultaneously maintaining the improved efficiency gains attributable to multi-junction solar cells. In short, using multi-junction solar cells in HCPV systems can offset the high material cost relative to silicon cells. Moreover, technology pathways to create multi-junction solar cells with more than 3 subcells and with efficiencies greater than 50% are in development, making the case for HCPV even more compelling.

The trend in HCPV is to operate at high concentrations (i.e., greater than or equal to 1000 suns) and use the smallest possible triple-junction solar cell in order to (1) minimize the cost contribution of the solar cell to the HCPV system cost and (2) maximize both solar cell efficiency and module output power.

In order to concentrate sunlight to 500-1000 suns or more in these HCPV systems, however, the optical system must meet a number of often competing requirements for low cost, compactness, reliability, optical transmission, and spectral purity. A number of reflective optical designs with excellent technical performance have been developed and deployed commercially (cf., e.g., Solfocus, Heliotrope) although the cost of these optical designs has made them impractical to use. Thus, the HCPV industry in large part has converged on the use of relatively inexpensive Fresnel refractive optics, with or without a secondary optical element.

The design of a Fresnel lens is well-known and a Fresnel lens is relatively simple and inexpensive to manufacture (see, e.g., P. Sansoni, et al. (2009), “Optics for Concentration on PV Cells”, in D. Goswami et al. (Eds.), Proceedings of ISES World Congress 2007, Springer, pp. 618-622; P. Sansoni, et al. (2009), “CPV Optics: Optical Design and Tests”, in A. V. Killian (Ed.), Solar Collectors: Energy Conservation, Design, and Applications, Nova Publishers, pp. 253-278; D. C. Miller et al. (2009), “Analysis of Transmitted Optical Spectrum Enabling Accelerated Testing of CPV Designs”, NREL/CP-520-44968).

One fundamental disadvantage of using a Fresnel lens or other classic lenses, however, is that chromatic aberration occurs whenever light experiences refraction (i.e., when light goes from one medium (e.g., vacuum, air, water, glass, etc.) to another medium and the angle of incidence of the light is not normal to the media interface). In the case of a Fresnel lens, this chromatic aberration increases as a function of distance away from the optical axis of a lens—that is, greater chromatic aberration is seen as one moves along a radius away from the center of a Fresnel lens. Because the index of refraction of an optical medium is a function of wavelength, different wavelengths are refracted to different degrees, which results in a spectrum of wavelengths being focused to different positions at a target. Additionally, as the distance from the optical axis increases, the magnitude of refraction increases, thereby compounding the problem. For a Fresnel lens in an HCPV application, the effect of the chromatic aberration is to fundamentally limit the focal ratio (i.e., the N or F-number) at which illumination can strike the active area of a solar cell. The incident light is, moreover, non-uniform in both intensity and wavelength. These variations in illumination lower the maximum power that can be output from a solar cell—and especially the output from triple-junction solar cells which operate best under uniform illumination.

When a concentration of 500 suns or more is targeted, chromatic aberration becomes an even greater concern. With a Fresnel lens alone, such higher concentrations are achieved by increasing the focal ratio (e.g., by increasing focal length) to reduce the amount of refraction needed. Increasing focal length, however, increases system size and volume, and consequently, system cost. Thus, use of a Fresnel lens alone forces an undesirable tradeoff in an HCPV system: (1) use a longer focal length, which increases the cost and the physical size of an HCPV system, or (2) reduce concentration, which ultimately increases the cell area required and reduces both the overall output and output efficiency of a solar cell.

Because of the difficulty of achieving the small spot size on the solar cell necessary for high solar concentration, while simultaneously maintaining a reasonable focal ratio (e.g., a focal length that is not much larger than the lens diameter) and minimizing chromatic aberration, a secondary optical element is typically use in conjunction with a Fresnel lens in modern HCPV systems. Such a secondary optical element is typically attached directly to a solar cell, and acts to increase the acceptance angle and acceptance aperture of light from a Fresnel lens, as well as homogenize the spectral and intensity variations of light from the primary (Fresnel) lens and thereby deliver a uniform irradiance to the solar cell. One problem with using a secondary optical element is that it is bonded with an adhesive directly to a solar cell to maintain a stable position on the solar cell. In addition, index matching adhesives are typically utilized to eliminate passage of light through an additional optical interface. When the solar cell is moved (during manufacture, bonding, and/or deployment), the mass of secondary optical element can introduce mechanical stress to, and potentially damage the solar cell. Other drawbacks to the primary-secondary optics arrangement are that (1) use of a secondary optical element drives up the manufacturing costs for an HCPV system by adding the cost of an additional component (the secondary optic) as well as the cost of attaching the secondary optical element directly to a solar cell and (2) mechanical stresses and bond effectiveness reduce yield. In practice, these additional costs don't tend to offset the additional power gains.

What is needed for a cost-effective HCPV system, then, is a superior optics design that optimizes (or minimizes) target spot size while reducing the focal ratio, minimizing chromatic aberration, eliminating the need for a secondary optical element, and reducing system size and manufacturing costs.

### SUMMARY

In one embodiment is provided a hybrid optical concentrator for concentrating solar energy comprising a total internal reflection (TIR)-mediated concentrator region and a Fresnel-mediated concentrator region.

In another embodiment is provided the hybrid optical concentrator wherein the TIR-mediated concentrator region comprises one or more features, each feature comprising: (a) an entry surface through which a light ray passes from air into an optical medium of the feature; (b) a reflector surface comprising a section angled such that an angle of incidence of the light ray traveling thereto from the entry surface is greater than a critical angle for the optical medium of the feature; and (c) an emitting surface angled such that the light ray traveling thereto from the reflector surface exits the optical medium of the feature therethrough and is refracted at an angle that focuses the light ray onto a target solar cell.

In yet another embodiment is provided a TIR-mediated optical concentrator having one or more features, each feature comprising: (a) an entry surface through which a light ray passes from air into an optical medium of the feature; (b) a reflector surface comprising a section angled such that an angle of incidence of the light ray traveling thereto from the entry surface is greater than a critical angle for the optical medium of the feature; and (c) an emitting surface angled such that the light ray traveling thereto from the reflector surface exits the optical medium of the feature therethrough and is refracted at an angle that focuses the light ray onto a target solar cell.

In still another embodiment is provided a method of designing a hybrid optical concentrator for concentrating solar energy, the method comprising: (a) designing a Fresnel-mediated concentrator region that encompasses a working range of a Fresnel optics; and (b) designing a total internal reflection (TIR)-mediated concentrator region having one or more designed features that encircle the Fresnel-mediated concentrator.

In another embodiment is provided the method of designing a hybrid optical concentrator for concentrating solar energy wherein designing the total internal reflection (TIR)-mediated concentrator region comprises: (a) using a generic annular feature as a model, the generic feature comprising: (i) an entry surface through which a light ray passes from air into an optical medium of the feature; (ii) a reflector surface comprising a section angled such that an angle of incidence of the light ray traveling thereto from the entry surface is greater than a critical angle for the optical medium of the feature; and (iii) an emitting surface angled such that the light ray traveling thereto from the reflector surface exits the optical medium of the feature therethrough and is refracted at an angle that focuses the light ray onto a target solar cell; (b) creating a designed feature from the model by modifying the emitting surface and the reflector surface of the model such that light exiting the designed feature through the emitting surface is focused to obtain an acceptable spot size on the target solar cell; (c) modifying the emitting surface and the reflector surface of the designed feature to eliminate shadowing when the designed feature is shadowed by a previously designed feature; (d) repeating steps (a), (b), and (c) to create another designed feature if a predetermined performance target has not been achieved; and (e) applying a merit function to fine-tune a best solution for each of the one or more designed features such that the designed features together concentrate solar energy at a desired concentration on the target solar cell.

In still another embodiment is provided the method of designing the hybrid optical concentrator for concentrating solar energy wherein designing the Fresnel-mediated concentrator region that encompasses a working range of a Fresnel optics comprises: (a) modeling a first Fresnel tooth within the Fresnel working range, the first Fresnel tooth having a first angle which determines an angle of refraction of light exiting the first Fresnel tooth and a location within the Fresnel working range; (b) modifying the first angle of the first Fresnel tooth to generate from light exiting the first Fresnel tooth a first lateral color spot of acceptable size on a target solar cell; (c) modifying the location of the first Fresnel tooth to center the first lateral color spot of acceptable size on the target solar cell; (d) modeling a next Fresnel tooth more medially within the Fresnel working range, the next Fresnel tooth having a next angle which determines an angle of refraction of light exiting the next Fresnel tooth; (e) modifying the next angle of the next Fresnel tooth to position a next lateral color spot of acceptable size from light exiting the next Fresnel tooth on the target solar cell; and (f) repeating steps (d) and (e) for another Fresnel tooth when the Fresnel working range is not complete.

### BRIEF DESCRIPTION OF DRAWINGS

FIG. 1 (a)-(c) show an assembled TIR hybrid concentrator according to one embodiment. FIG. 1(a) shows the assembled TIR hybrid concentrator from an oblique view. FIG. 1(b) shows the assembled TIR hybrid concentrator from a top-down view. FIG. 1(c) shows the assembled TIR hybrid concentrator from a cross-sectional view through an optical center of the TIR hybrid concentrator.

FIG. 2 (a)-(d) is a schematic illustrating a method of assembly of a TIR hybrid concentrator according to one embodiment. FIG. 2(a) is a cross-section through an optical center of the TIR hybrid concentrator illustrating a Fresnel concentrator molded with a first set of TIR concentrator features. FIG. 2(b) is a cross-section through an optical center of the TIR hybrid concentrator illustrating a second set of TIR concentrator features; FIG. 2(c) is an oblique view of the second set of TIR concentrator features; and FIG. 2(d) is a cross-section of the fully assembled TIR hybrid concentrator according to one embodiment.

FIG. 3 is a schematized representation of a concentrator module from an oblique top-down perspective according to one embodiment.

FIG. 4(a) and FIG. 4(b) together form a schematic illustrating passage of light rays through a TIR concentrator feature to a detector according to one embodiment. FIG. 4(a) is a schematic illustrating passage of light rays through a TIR concentrator feature according to one embodiment. FIG. 4(b) is a schematic illustrating the light rays focused on a detector after passage through the TIR concentrator feature according to one embodiment.

FIG. 5 is a flowchart illustrating a method of designing a Fresnel concentrator region of a TIR hybrid concentrator according to one embodiment.

FIG. 6 is a schematic illustrating determination of lateral color spot sizing for a Fresnel concentrator region.

FIG. 7 is a flowchart illustrating a method of designing a TIR concentrator region of a TIR hybrid concentrator region according to one embodiment.

FIG. 8(a) and FIG. 8(b) together form a schematic illustrating determination of lateral color spot sizing for a TIR concentrator region according to one embodiment. FIG. 8(a) is a schematic illustrating how light rays pass through a TIR concentrator region to strike a detector. FIG. 8(b) is a magnified view of the light rays striking the detector after exiting a TIR concentrator region.

FIG. 9 is a scatter plot showing lateral color spot size (λ=425 nm, 1000 nm) and solar concentration as a function of F-number (focal length/diameter) for both a Fresnel concentrator at focal lengths of 120, 163, and 200 mm and a TIR concentrator at focal lengths of 120 and 163 mm.

FIG. 10 is a graph showing modeled distributions of irradiance (W/m²) as a function of coordinate location across a solar cell for energy concentrated by a Fresnel concentrator region, a TIR concentrator region, and a TIR hybrid concentrator.

FIG. 11 is a top-down view of a modeled power distribution map showing a two-dimensional power distribution incident on of a 5.5 mm solar cell receiving light passed through a TIR hybrid concentrator with a focal length of 120 mm and a geometrical concentration of 1000 suns according to one embodiment.

FIG. 12 is a top-down view of a modeled power distribution map showing a two-dimensional power distribution incident on a 5.5 mm solar cell receiving light passed through a Fresnel concentrator region of a TIR hybrid concentrator with a focal length of 120 mm and a geometrical concentration of 326 suns according to one embodiment.

FIG. 13 is a top-down view of a modeled power distribution map showing a two-dimensional power distribution incident on a 5.5 mm solar cell receiving light passed through a TIR concentrator region of a TIR hybrid concentrator with a focal length of 120 mm and a geometrical concentration of 674 suns according to one embodiment.

FIG. 14 is a top-down view of a modeled two-dimensional power distribution incident on a 5.5 mm solar cell receiving light passed through a Fresnel lens (without a secondary optics) with a focal length of 120 mm and a geometrical concentration of 425 suns.

FIG. 15 is a top-down view of a modeled power distribution map showing a two-dimensional power distribution incident on a 5.5 mm solar cell receiving light passed through a standard Fresnel lens (with a secondary optics) with a focal length of 120 mm and a geometrical concentration of 425 suns.

FIG. 16 is a top-down view of a modeled two-dimensional power distribution incident on a 5.5 mm solar cell receiving light passed through a Fresnel lens (without a secondary optics) with a focal length of 200 mm and a geometrical concentration of 1000 suns.

FIG. 17 is a top-down view of a modeled power distribution map showing a two-dimensional power distribution incident on a 5.5 mm solar cell receiving light passed through a standard Fresnel lens (with a secondary optics) with a focal length of 200 mm and a geometrical concentration of 1000 suns.

FIG. 18(a) and FIG. 18(b) show embodiments of an assembled TIR concentrator. FIG. 18(a) shows an oblique view of an assembled linear TIR concentrator according to one embodiment. FIG. 18(b) shows an oblique view of an assembled annular TIR concentrator according to one embodiment.

### DETAILED DESCRIPTION OF THE INVENTION

Embodiments described herein disclose a TIR concentrator optics which can be used alone or in concert with Fresnel concentrator optics as a primary optic to concentrate solar energy. The embodiments discussed herein utilize a novel TIR concentrator design to enable lower F-number optical systems, resulting in smaller systems with higher concentrations of solar energy than is currently attainable with Fresnel lenses (alone or in conjunction with secondary optics) while simultaneously minimizing chromatic aberration experienced with deployment of Fresnel lenses (alone or in conjunction with secondary optics).

Embodiments of TIR concentrator optics described herein offer several optical advantages over current technologies for solar energy concentration, to wit: TIR concentrator optics can (1) be tuned to solar cell size to optimize energy output from an HCPV system; (2) achieve high solar concentrations (e.g., in excess of 2500 suns) with short focal lengths—thereby providing useful concentrator optics technology today as well as in the future as solar cells evolve to increase concentration levels and solar energy conversion capacity; (3) concentrate light in a smaller, more localized area of a solar cell—thereby allowing a smaller solar cell size to be used in HCPV systems while maintaining or exceeding net output relative to currently available commercial HCPV systems—and consequently reducing thermal issues and lowering cell cost contributions to HCPV system costs; (4) decrease focal length (relative to current Fresnel technologies) which in turn can minimize HCPV module form factors—thereby reducing materials and costs contributions to HCPV system costs; (5) decrease chromatic aberration as TIR concentrator optics increase in size (in contrast to Fresnel optics in which chromatic aberration is increased as lens size increases)—thereby increasing power incident on a given solar cell relative to power incident on a Fresnel lens of equivalent area; (6) significantly change the direction of light rays without introducing chromatic aberration—thereby enabling very high solar concentrations and eliminating a need for a secondary optics to homogenize light onto a solar cell, and consequently decreasing the cost of an HCPV module; and (7) offer performance advantages (e.g., higher net efficiency) relative to HCPV systems deploying current Fresnel technologies.

Embodiments of the TIR concentrator optics described herein offer other non-optical benefits, to wit: (1) no coating is needed inside an HCPV module to maximize solar focus onto a solar cell; (2) no optical matching material is needed to adhere a secondary optics to a solar cell; (3) no alignment of a secondary optics is necessary; (4) ease of manufacturability and assembly; and (5) low manufacturing costs. Each of these benefits leads to a reduction in manufacturing costs for an HCPV system. As a secondary non-optical benefit, elimination of a secondary optics reduces failures in the HCPV system by eliminating mechanical stress on the solar cell as the HCPV system is built, transported, deployed, and/or moved during solar tracking.

One embodiment of TIR concentrator optics is a TIR hybrid concentrator which comprises both Fresnel concentrator optics and TIR concentrator optics.

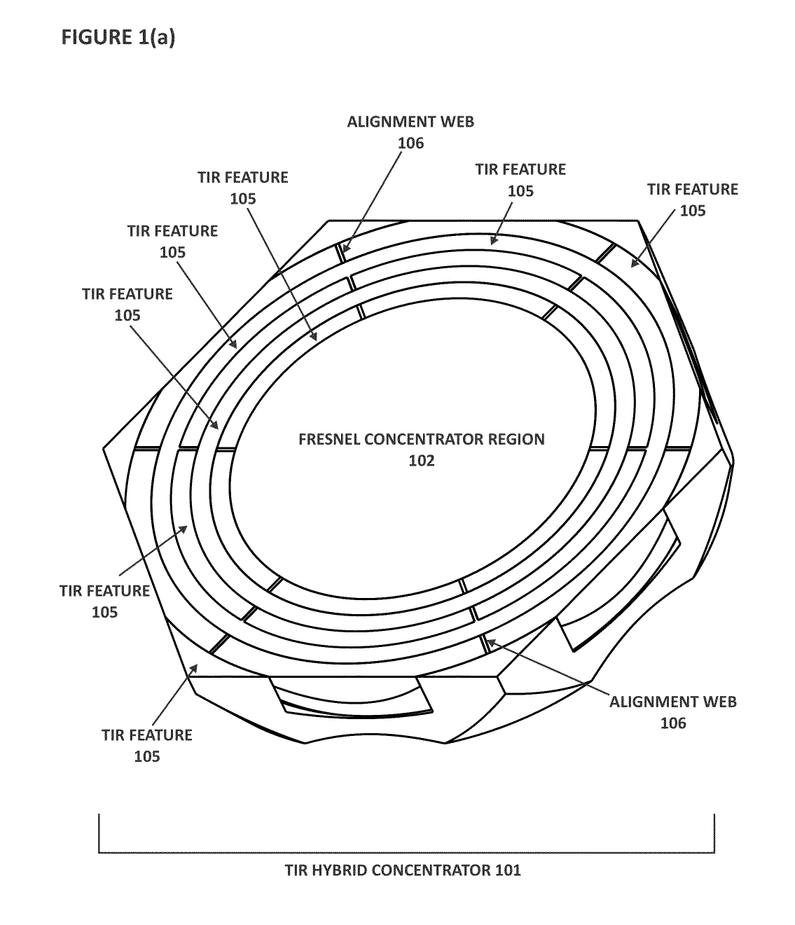

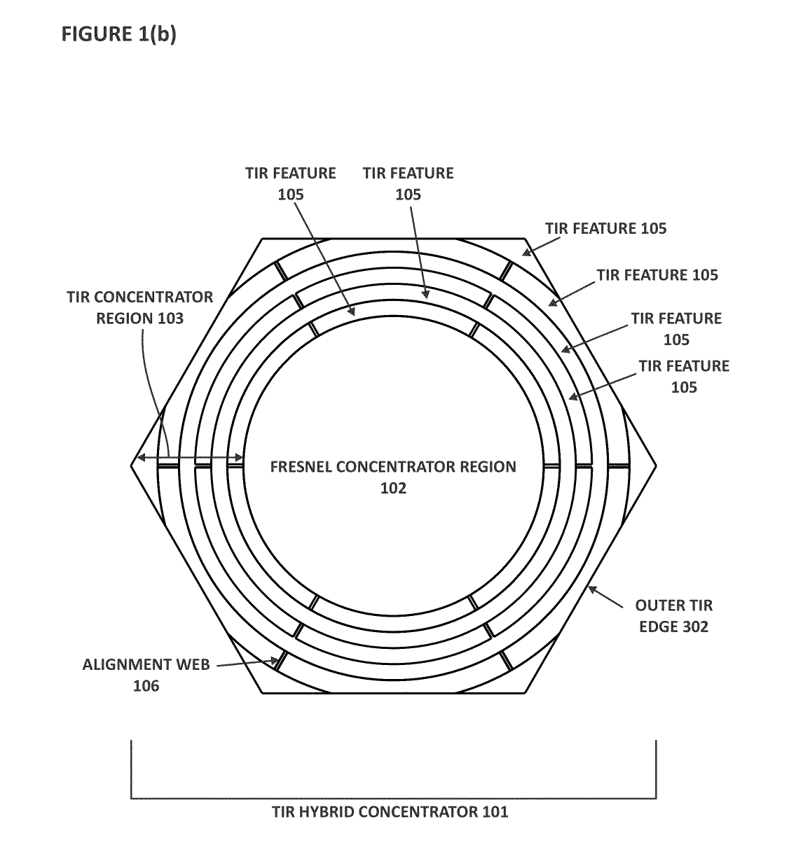

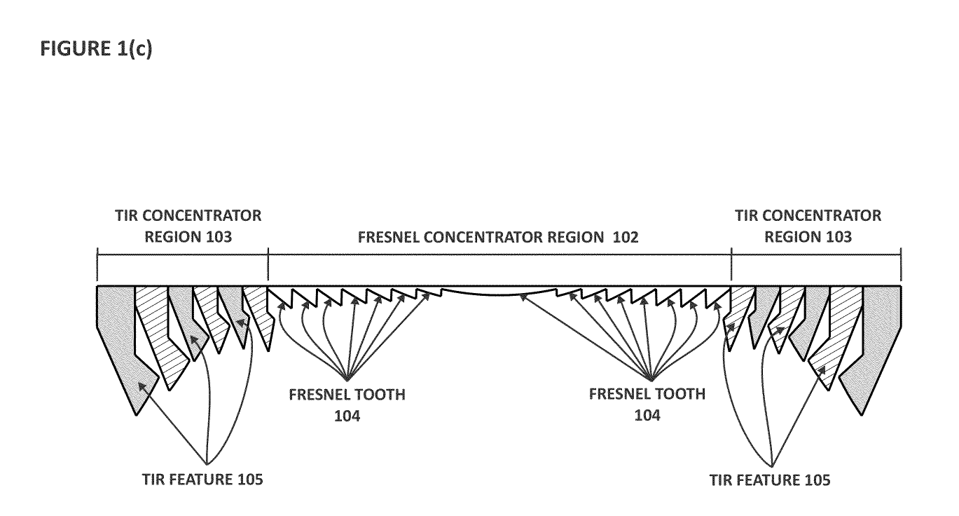

One embodiment of a TIR hybrid concentrator is presented in FIGS. 1(a), (b), and (c). As shown in an oblique view in FIG. 1(a), in a top-down view in FIG. 1(b), and in a cross-sectional view in FIG. 1(c), a TIR hybrid concentrator 101 comprises a circular central Fresnel concentrator region 102 and a TIR concentrator region 103 encircling Fresnel concentrator region 102.

As shown in the figures, Fresnel concentrator region 102 comprises, in one embodiment, a standard Fresnel lens as used for HCPV concentrator optics, typically with multiple concentric annular lenses. In preferred embodiments, Fresnel concentrator region 102 comprises a Fresnel concentrator region designed according to a method described herein. Fresnel concentrator region 102 comprises multiple Fresnel teeth 104. TIR concentrator region 103 comprises multiple concentric rings of TIR features 105 (discussed in more detail elsewhere herein) connected by alignment webs 106 and alignment grooves (not shown in FIG. 1(a), (b), or (c), but discussed elsewhere herein). TIR concentrator region 103 preferably comprises 6 TIR features 105 for a 5.5 mm solar cell with an active area of 5.5. mm (“5.5 mm solar cell”), although TIR concentrator region 103 can comprise more or fewer TIR features 105 as desired.

In one embodiment, Fresnel concentrator region 102 comprises silicone, glass or plastic. TIR features 105 preferably comprise silicone, but can comprise glass, plastic (e.g., PMMA, acrylic, or polycarbonate), or other lens optical media.

In one embodiment, Fresnel concentrator region 102 and TIR concentrator region 103 are optionally bonded to a cover material (not shown) with an adhesive (e.g., silicone, acrylic adhesive, epoxy, or resin). The cover material comprises glass or another transparent material such as a plastic, with or without a coating, or a multilayer coating. The cover material preferably comprises a translucent glass.

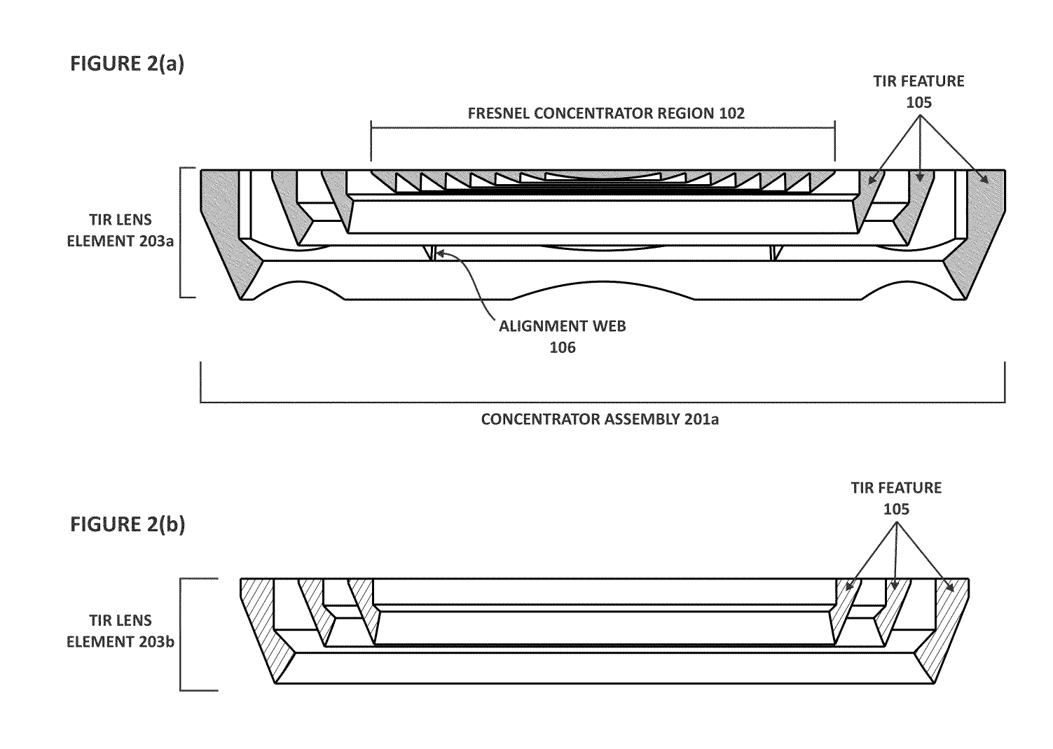

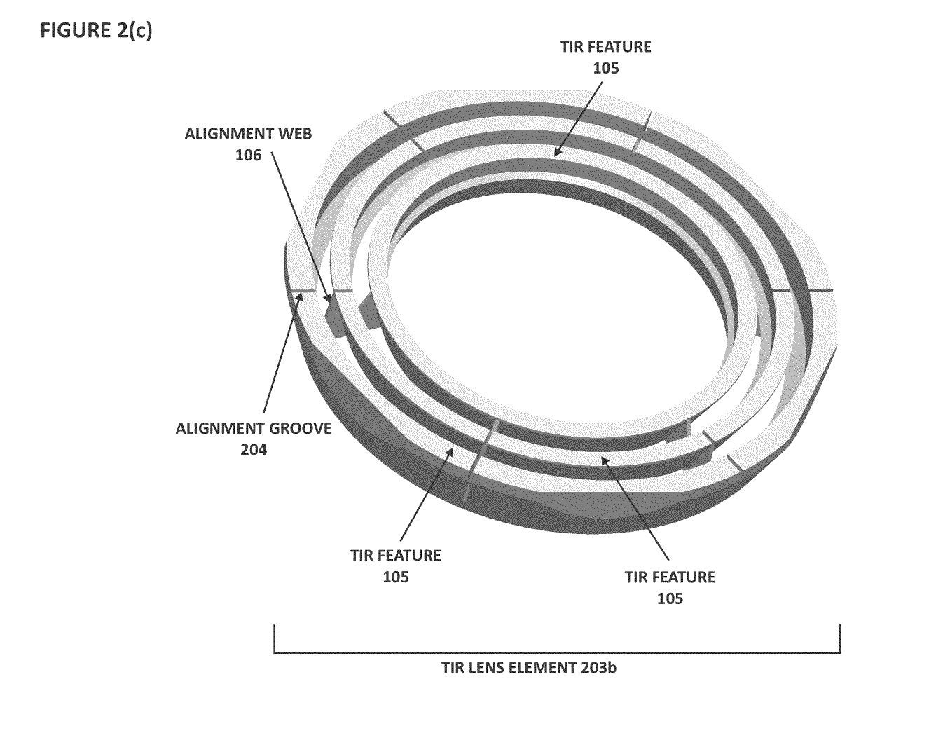

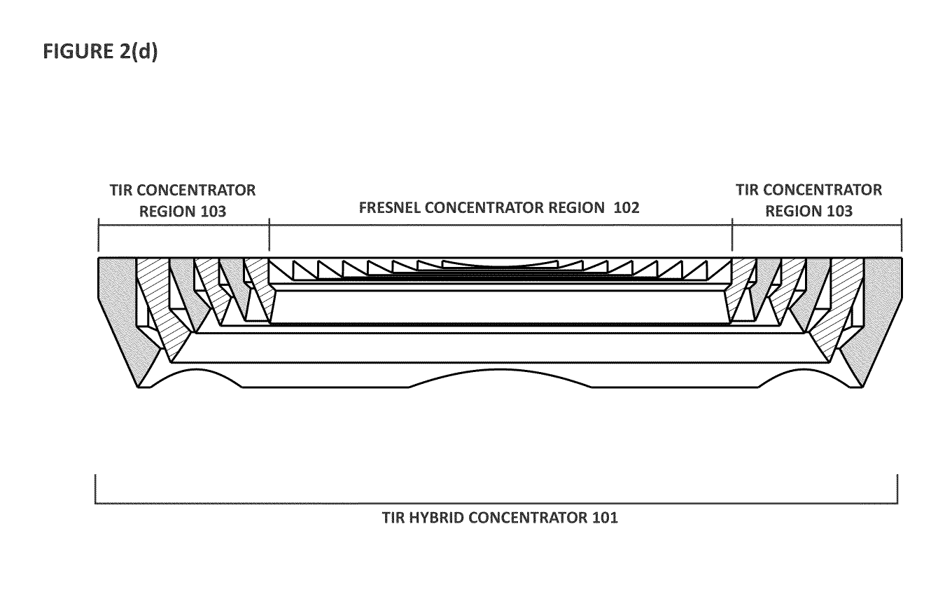

Referring now to FIGS. 2(a)-(d), assembly of TIR hybrid concentrator 101 will be described according to one embodiment. In a preferred embodiment, TIR hybrid concentrator 101 is manufactured as 2 pieces: a Fresnel concentrator region 102 and a TIR lens element 203a, preferably molded as a one piece concentrator assembly 201a (as shown in FIG. 2(a)), and a TIR lens element 203b (as shown in FIGS. 2(b) and (c)). TIR lens element 203a comprises multiple TIR features 105 arranged in concentric rings, with the number, size, and shape of TIR features 105 dependent on desired design parameters (discussed elsewhere herein). TIR lens element 203a further comprises periodic alignment webs 106 interrupting TIR features 105 at multiple sites. TIR lens element 203b likewise comprises multiple TIR features 105 arranged in concentric rings, with the number, size, and shape of TIR features 105 dependent on desired design parameters (discussed elsewhere herein). TIR lens element 203b further comprises periodic alignment grooves 204 (best visualized in the oblique view of FIG. 2(c)) interrupting TIR features 105 at multiple sites. Importantly, TIR features 105 of TIR lens element 203a are designed to be offset from TIR features 105 of TIR lens element 203b such that TIR lens elements 203a and 203b can be slotted together during assembly to form one TIR concentration region 103. Alignment webs 106 and alignment grooves 204 are used to align TIR lens element 203a and TIR lens element 203b.

Designing and manufacturing TIR hybrid concentrator 101 in 2 pieces allows TIR features 105 to nest densely within TIR concentrator region 103. A 2-piece construction, moreover, offers other benefits, to wit, generating leeway on the geometry for each TIR feature 105, minimizing the mass of material needed for TIR region 103, and providing room for adjacent features.

As a preferred assembly step in one embodiment, Fresnel concentrator region 102 and TIR concentrator region 203a (together forming concentration assembly 201, as shown in FIG. 2(a)) are bonded to a cover material. In a second step, TIR lens element 203b is bonded to concentrator assembly 201 (and preferably to the cover material) to form TIR hybrid concentrator 101 (shown in cross-section in FIG. 2(d)). Importantly, TIR lens elements 203a and 203b are designed and manufactured so that when TIR lens element 203b is fitted to concentrator assembly 201, alignment webs 106 of TIR lens element 203b slide into alignment grooves 204 of TIR lens element 203a. Thus, as shown in FIG. 2(d), when TIR hybrid concentrator 101 is fully assembled, TIR features 105 (hatched) from TIR lens element 203b are interdigitated with TIR features 105 (shaded) from TIR lens element 203a. Thus, in a preferred embodiment, each TIR feature annulus interfaces with adjacent TIR feature annuli, thereby forcing concentricity of TIR features 105 within TIR hybrid concentrator 101.

TIR features 105 need not be identical, and in one embodiment, TIR features 105 differ in shape from adjacent TIR features 105. Thus, molding of a TIR concentrator and/or a TIR hybrid concentrator is preferred as molding allows creation of complex structures that normally would not be manufacturable in a cost-effective manner.

In a preferred embodiment, concentrator assembly 201 (comprising TIR lens element 203a and Fresnel concentrator region 102), and TIR lens element 203b are bonded to a cover material with a silicone adhesive, although these elements can alternatively be bonded to a cover material with other optical adhesives. As described elsewhere herein, silicone is a preferred material for TIR features 105, so use of silicone to attach TIR features 105 to a cover material eliminates one optical media interface through which light rays must travel, and thereby eliminates a 4% loss in efficiency of a solar cell.

In another embodiment, concentrator assembly 201 (comprising TIR lens element 203a and Fresnel concentrator region 102) and TIR lens element 203b are bonded to a cover (e.g., made of glass or plastic, or glass with an anti-reflective coating) of a module array box comprising multiple CPV sub-modules (each sub-module having a single solar cell, a single receiver, optics, and other related components such as interconnection and mounting) for ease of replacement of cover material in the field.

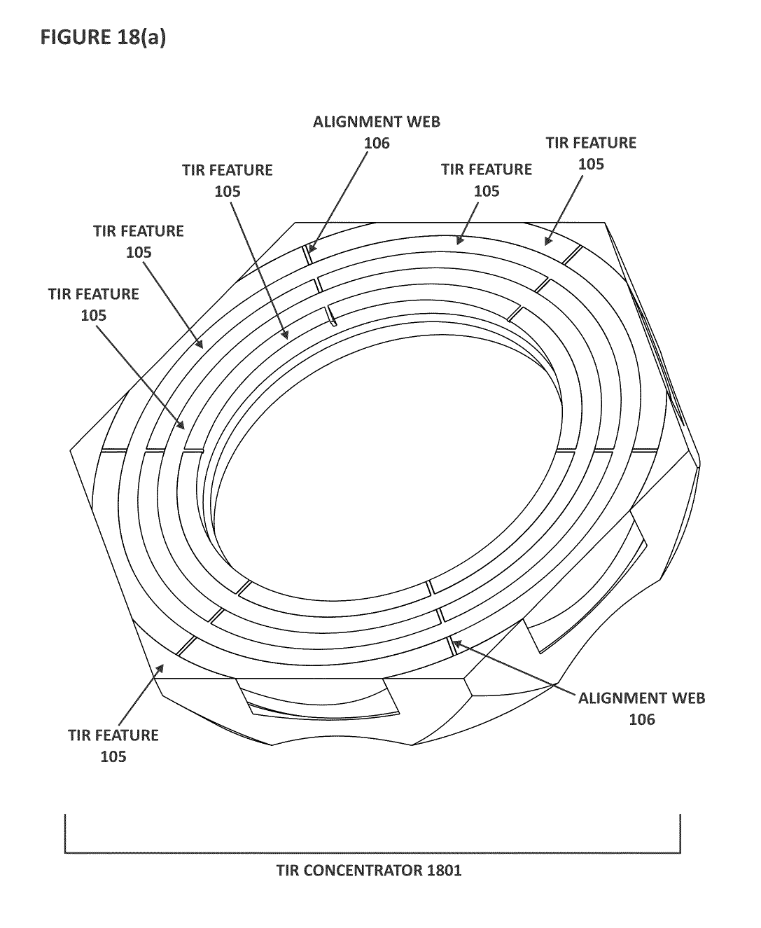

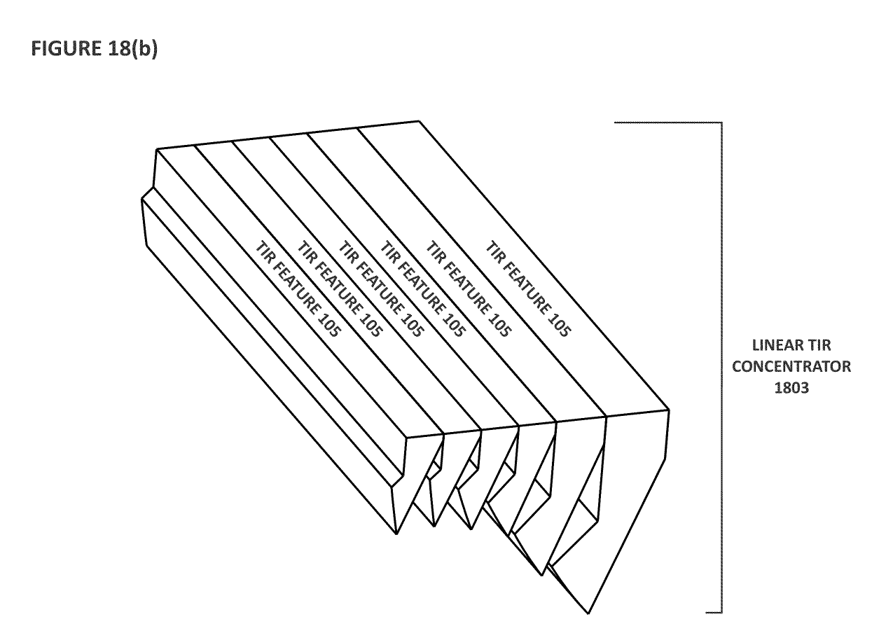

TIR concentrator optics need not be a TIR hybrid concentrator. In some embodiments, as shown in FIG. 18(a), a TIR concentrator 1801 comprises TIR features 105 without Fresnel optics (i.e., without Fresnel concentrator region 102). TIR concentrator optics, moreover, need not be circular. As shown in FIG. 18(b), in one embodiment, linear TIR concentrator 1803 comprises a linear array of TIR features 105 without a Fresnel concentrator region. Such a linear TIR concentrator can be used to concentrate light along a rectangular solar cell to decrease current decline as energy travels to connective bus bar regions, thereby improving efficiency of the solar cell.

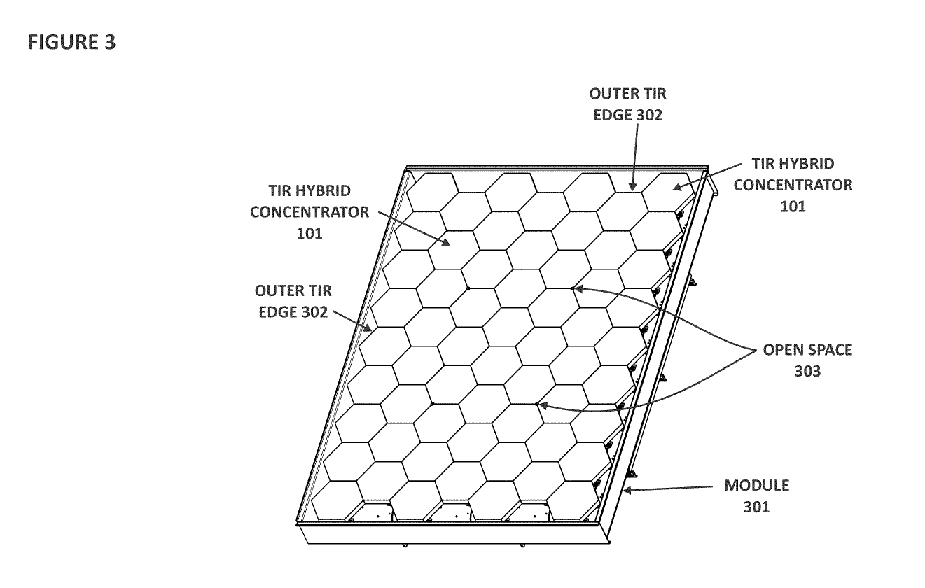

In various embodiments, TIR concentrator optics can be deployed within modules comprising multiple concentrator receivers, optics, and other related components. One such embodiment is shown from a top-down perspective in FIG. 3. In a preferred embodiment as shown in the figure, TIR hybrid concentrators are manufactured such that outer TIR edges 302 of TIR hybrid concentrator 101 is molded to form a hexagonal outer perimeter of TIR hybrid concentrator 101. A hexagonal outer perimeter provides a higher packing factor for a given sized module. Optional open spaces 303 among TIR hybrid concentrators 101 provide an accessible space for tooling, support structures, etc.

In various embodiments, TIR hybrid concentrator 101 can, but need not, be deployed with a secondary optical concentrator—for example, to increase acceptance angle, increase aperture, and/or homogenize illumination. In a preferred embodiment, TIR hybrid concentrator 101 is deployed without a secondary optical concentrator

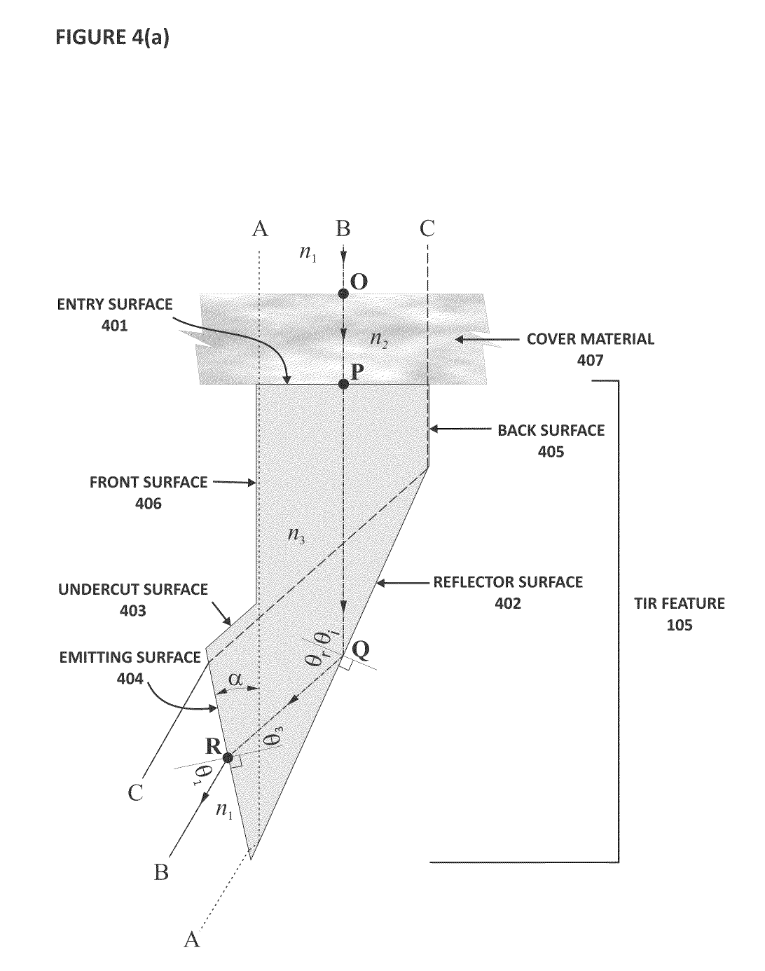

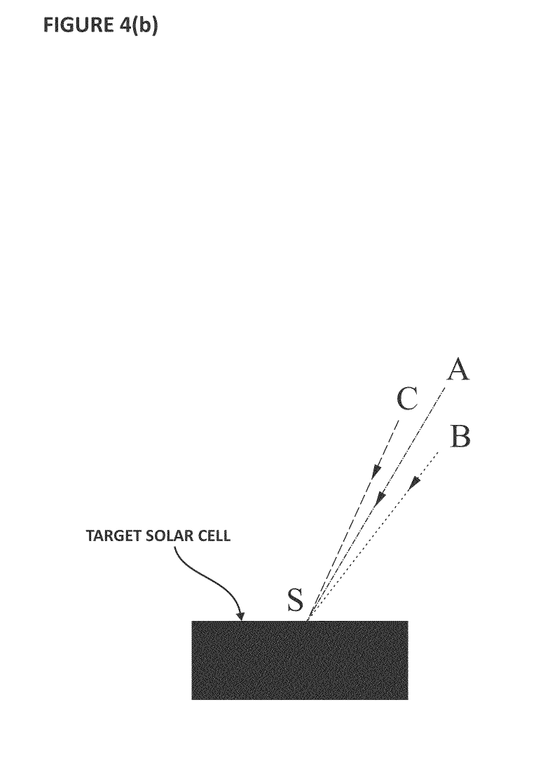

To facilitate description of embodiments of TIR concentrator optics and TIR features 105 as described herein, as well as embodiments of methods of designing TIR concentrator optics and features as described herein, and specifically with reference to FIGS. 4(a) and (b), the following terms are defined as follows:

Concentration: Concentration is defined as

$$C = \frac{{Area}_{lens}}{{Area}_{solar cell}}$$

Direct Normal Irradiance (DNI): DNI is the amount of solar radiation received per unit area by a surface that is always held perpendicular (or normal) to the rays that come in a line from the direction of the sun at its current position in the sky. Because DNI varies by geographical location and time of day, energy output is typically standardized to a DNI of 1000 W/m². This standardization allows comparison of HCPV system outputs across geographical locations.

Irradiance: Power of electromagnetic radiation per unit area incident on surface (e.g., first surface of a lens, surface of a solar cell, etc.). Irradiance is typically measured in W/m².

Ray: A graphical or mathematical representation of the propagation of electromagnetic radiation (light) through the optical system. Ray(s) can be synonymous with wave(s).

Optical Interface (or interface): A boundary (e.g., plane or surface) between optical media.

Optical Media: Media permitting the transmission of electromagnetic radiation.

Refraction: A change in direction of an electromagnetic radiation (ray or wave) due to a change in the index of refraction created by a change in the optical media. The direction of a refracted ray is described by Snell's Law.

Index of Refraction (10R): A dimensionless number that describes how electromagnetic radiation propagates through a media. The index of refraction (n) is defined as

n=c/v

where c is the speed of light in vacuum and v is the speed of light in the media.

Angle of Incidence (θᵢ): The angle between a ray incident on a surface and the vector perpendicular to the surface at the point of incidence (“the normal”).

Angle of Reflection (θᵣ): The angle between a ray direction after intersection with an optical interface, undergoing reflection, and the vector perpendicular to the surface at the point of incidence (the “normal”).

Angle of Refraction: The angle between a ray direction after intersection with an optical interface, undergoing refraction, and the vector perpendicular to the surface at the point of incidence (the “normal”) within the new optical media.

Snell's Law: A formula describing the relationship between an angle of incidence and an angle of refraction which states that the ratio of the sines of the angles of incidence and refraction is equivalent to the ratio of the phase velocities in the two media, or equivalent to the reciprocal of the ratio of the indices of refraction. Mathematically,

n₁ sin θ₁=n₂ sin θ₂

Snell's law is used to determine the direction of light rays passing through refractive optical media with different indices of refraction.

Critical Angle (θᵣ): A critical angle is the largest possible angle of incidence at which a ray can be refracted when striking an optical interface. In such a case, the refracted ray travels along the optical interface between the two optical media. The critical angle is the angle of incidence above which total internal reflection occurs. The critical angle is defined by rearranging and solving Snell's law such that the refracted ray is 90°. Thus, Snell's law

n₁ sin θᵣ=n₂ sin θ₂

becomes

n₁·sin 90°=n₂·sin θ_{c}.

Solving for the critical angle

$${θ}_{c} = {sin}^{- 1} ( \frac{{n}_{1}}{{n}_{2}} ) .$$

Total Internal Reflection (TIR): A phenomenon that occurs when an incident ray, traveling from an optical medium with a higher refractive index (e.g., water) to a second optical medium with a lower refractive index (e.g., air), strikes the optical interface (e.g., the air/water interface) at an angle larger than a particular critical angle with respect to normal to the interface. The propagating ray in such a case is completely reflected by the medium boundary at an angle equal in magnitude to the angle of incidence, a phenomenon known as total internal reflection (“TIR”). TIR can only occur when a ray travels from an optical media with a higher index of refraction to an optical media with a lower index of refraction.

TIR feature 105 according to one embodiment is schematized in FIG. 4(a). In one embodiment, TIR feature 105 comprises a lens optical media. TIR feature 105 comprises an entry surface 401, a reflector surface 402, an undercut surface 403, an emitting surface 404, a back surface 405 (a non-angled section of reflector surface 402), and a front surface 406 (a non-angled section of undercut surface 403).

TIR feature 105 is designed and manufactured such that a portion of reflector surface 402 is angled to enable total internal reflection of light rays entering TIR feature 105 (described elsewhere herein). Reflector surface 402 is defined by its slope and radius (which can be generically aspheric or free-form). A primary purpose of reflector surface 402 is to redirect incident light correctly through emitting surface 404 to exit TIR feature 105 so as to strike a target solar cell. A secondary purpose of reflector surface 402 is to assist in focusing light onto the target solar cell.

Undercut surface 403 is designed and manufactured with an undercut to enable proper orientation of emitting surface 404 such that light rays reflected from reflector surface 402 exit TIR feature 105 through emitting surface 404 (described elsewhere herein). Emitting surface 404 (which can be generically aspheric or free-form) is defined by its slope and/or radius. The length of undercut surface 403 is defined by the magnitude of a (discussed elsewhere herein).

Back surface 405, front surface 406, and undercut surface 403 are inert in that none of these surfaces is involved in reflection or refraction of light rays. The purpose of undercut surface 403, back surface 405, and front surface 406 are to enable nesting of a TIR feature 105 with adjacent TIR features 105, rather than to impact performance of TIR feature 105. As an example, if emitting surface 404 is extended to intersect entry surface 401, undercut surface 403 and/or front surface 406 could cease to exist, but TIR feature 105 would nevertheless function as intended.

A primary purpose of emitting surface 404 is to focus light emitted from TIR feature 105 onto a target solar cell. As described elsewhere herein, varying the slope of emitting surface 404 (i.e., a) changes the direction of light emitted from TIR feature 105 whereas changing the shape (e.g., radius) of emitting surface 404 controls the convergence of light rays on the cell.

A functional description of one embodiment of a TIR feature 105 will be provided with reference to a generic TIR feature 105 in FIGS. 4(a) and (b). For the purposes of this description, passage of light ray B through TIR feature 105 is described.

As light ray B travels through TIR feature 105, light ray B passes through multiple boundaries (each, an “interface”) between different optical media. For example, light ray B travels through multiple optical segments defined by interfaces including segments O→P, P→Q, Q→R, and R→S wherein O, P, Q, R, and S constitute discrete interfaces. In various embodiments, surfaces that create interfaces O, P, Q, and R can be planar, spherical, aspheric, freeform, and need not be axis-symmetric.

These optical interfaces segregate optical media affecting light passage through the TIR concentrator. In one embodiment depicted within FIG. 4, the optical media divided by optical interfaces are defined as follows:
a first optical medium with an index of refraction defined as n₁ (e.g., air);
a second optical medium with an index of refraction defined as n₂ (e.g., cover material 407); and
a third optical medium with an index of refraction defined as n₃, (e.g., TIR feature 105 material, e.g., silicone).

One of skill in the art will recognize that optical media other than those suggested above (and with different indices of refraction) can also be used, for example, to control energy loss due to passage through interfaces with different indices of refraction. As is known, energy of light ray B is reduced by approximately 4% for each significant change of optical media through which light ray B passes (due to Fresnel reflection off the interface).

Interface O is defined as a boundary at which light ray B exits the first optical medium (e.g., air) and enters cover material 407. Light ray B passes from the first optical medium (e.g., air) into the second optical medium (e.g., cover material 407). Interface O will typically be normal to entry surface 401 of TIR feature 105.

Interface P is defined as an upper boundary of TIR feature 105—that is, an interface through which light ray B exits cover material 407 and passes through entry surface 401 to enter TIR feature 105. Light ray B typically passes from the second optical medium (e.g., cover material 407) to the third optical medium (e.g., TIR feature 105) at interface P. In another embodiment, interface O may alternatively change to the first optical medium (e.g., if there is no cover material 407) or have an angle of incidence >0° (e.g., light ray B can enter cover material 407 at an angle rather than be normal to entry surface 401).

Interface Q is defined as a boundary along an angled section of reflector surface 402 of TIR feature 105 through which light ray B could theoretically exit reflector surface 402 to enter a different optical media (e.g., the first optical medium), or by which light ray B could theoretically be refracted. However, because of the design of reflector surface 402, and more specifically, the design of the angled portion of reflector surface 402 (described elsewhere herein), light ray B instead experiences total internal reflection. Thus, light ray B strikes interface Q at reflector surface 402 at an angle of incidence (θᵢ) greater than a critical angle (θ_{c}) for that interface. Light ray B is consequently redirected by (θᵢ+θᵣ) degrees (i.e., towards emitting surface 404) without introducing chromatic aberration. One of skill in the art will understand that other light rays (e.g., light ray A, light ray C, and intervening light rays between those two light rays) will strike interface Q at different positions along reflector surface 402 of TIR feature 105, as illustrated in FIG. 4(a).

Interface R is defined as a lower boundary of TIR feature 105—that is, an interface through which light ray B exits TIR feature 105 through emitting surface 404 and passes into another lens optical medium (which can be the same as the first optical medium (e.g., air) or otherwise). Exiting light ray B experiences refraction to a degree described by equation

$${θ}_{1} = {sin}^{- 1} \frac{{n}_{3}}{{n}_{1}} sin {θ}_{3}$$

where θ₁ is an angle of refraction of light ray B as it exits TIR feature 105, and θ₃ is an angle of incidence of light ray B at interface R after having been redirected by total internal reflection from interface Q.

Interface S is defined as an upper boundary of a detector (e.g., a target solar cell) through which light ray B exits the first optical media (e.g., air) and enters the detector. Actual energy incident at interface S includes rays that account for the angle subtended by the optical concentrator and chromatic aberrations introduced through the system.

One of skill in the art will recognize that light rays A, B, and C shown in FIGS. 4(a) and (b) are general approximations, and that light rays A and C, as well as other incident light rays between light rays A and C follow the same interface interactions as described for light ray B. As seen in FIGS. 4(a) and (b), incident light rays A and B (as well as other incident light rays between light rays A and C) also pass through interfaces O, P, Q, R, and S. Notably, each incident light ray strikes interface Q at different positions along reflector surface 402, and exits TIR feature 105 through different R interface positions along emitting surface 404.

In a preferred embodiment, a TIR hybrid concentrator is designed such that a Fresnel concentrator optics surrounded by a TIR concentrator optics. For ease of manufacturing, entry surface 401 is preferably flat so as to be easily bonded with cover material 407. If entry surface 401 of TIR feature 105 is coincident to an uncoated flat surface, only 4% of incident energy is lost through Fresnel reflection off the interface.

Silicone is a preferred material for TIR features 105 because use of silicone (as opposed to other lens materials such as PMMA) allows TIR features 105 to be manufactured with injection molding while allowing non-uniform thickness and thicker cross-section geometry without sink marks (caused by hot plastic in thick sections of parts) and retaining good cycle time (i.e., how fast parts can be molded) especially compared to materials such as PMAA which require longer cycle times for thick parts. Use of a molding process for lens manufacturing, moreover, allows multiple pieces to be made from one mold.

Before designing a TIR hybrid concentrator, concentrator parameters are determined, to wit: a target system power output (e.g., 20 to 30 W per receiver); a target power per unit area (e.g., 300 W/m²); a target power per unit volume (e.g., 1.5 W/L); a target F-number (e.g., N<0.8); a target solar concentration (e.g., 1000 suns); a target focal length (e.g., 120 mm); a target lens material (e.g., silicone); a target solar cell size (e.g., 5.5 mm); and a critical angle for the lens material. Once a target lens material has been selected, an index of refraction therefor and a critical angle therefor can be determined. A preferred design goal is to minimize the F-number (by minimizing focal length) and maximize solar concentration in order to minimize HCPV system costs. A shorter focal length reduces HCPV system costs by reducing form factor size of the system unit and reducing shadowing on adjacent module arrays, which in turn reduces the real estate needed for, and consequently the cost of deployment. Increasing solar concentration increases energy output from a HCPV system. A preferred approach is to determine concentrator parameters that are achievable, and then minimize parameters to optimize concentrator parameters within achievable limits.

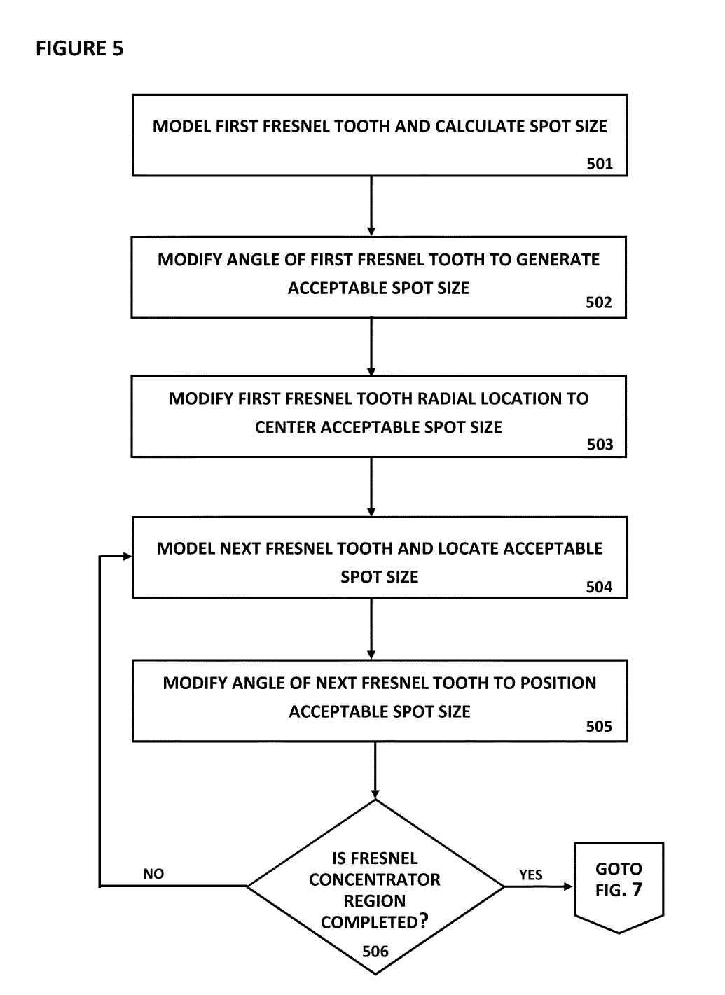

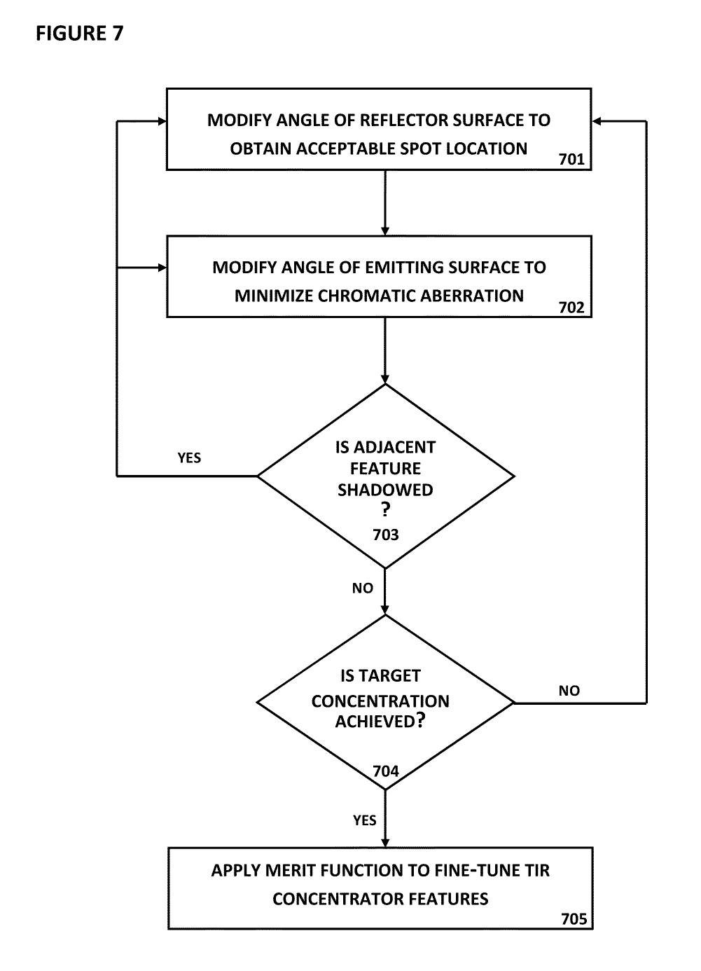

A method of designing a TIR hybrid concentrator according to one embodiment is diagrammed in the flowcharts shown in FIGS. 5 and 7. As a first step, a Fresnel concentrator region is designed. A method of designing a Fresnel concentrator region according to one embodiment is diagrammed in FIG. 5. A design goal is to determine a working range (along a radius from an optical center of a Fresnel concentrator region) within which Fresnel optics concentrate light well, and then to design Fresnel teeth that extend along a radius of that working range, but no further. Once this Fresnel concentrator region is designed (steps 501-506), a more lateral TIR concentrator region (along which TIR concentrator optics concentrate light well) can be designed (steps 701-706).

In designing a Fresnel concentrator region, multiple Fresnel teeth are designed laterally to medially within a working range of Fresnel concentrator region 102. The extent of this working range is defined by the technology transfer point (i.e., the point at which TIR technology becomes more effective than the Fresnel technology). Concentration curves can be generated for Fresnel lenses that allow an optical designer to determine an F-number for a given solar cell size and a given focal length. These concentration curves can be used to establish a starting point for defining the radial extent of the working range—that is, the position of the most lateral, yet first Fresnel tooth to be designed.

A Fresnel concentrator region can be designed such that (1) all of the Fresnel teeth have a substantially uniform height; (2) all of the Fresnel teeth have a substantially uniform width; or (3) some Fresnel teeth have a substantially uniform height whereas some other Fresnel teeth have a substantially uniform width. If, as in (1), all of the Fresnel teeth have a substantially uniform height, then the Fresnel teeth become progressively wider as the Fresnel concentrator region is designed laterally to medially. If, as in (2), all of the Fresnel teeth have a substantially uniform width, then the Fresnel teeth become progressively shorter as the Fresnel concentrator region is designed laterally to medially. One of skill in the art will recognize that manufacturing concerns (e.g., thickness of lens material, method of lens manufacturing) can impact the desirable height and width of the Fresnel teeth. Thus, determination of a desired height and/or width of the Fresnel teeth can necessitate a balancing of tooth size versus energy loss per Fresnel tooth, or a balancing of cost versus desired energy output. In a preferred embodiment, a width and reasonable height for a first Fresnel tooth is predetermined and subsequent Fresnel teeth—except for the centermost Fresnel tooth—each have the same width. In this embodiment, the final Fresnel tooth (i.e., the most medial, or centermost Fresnel tooth) has the sharpest radius and a slope shallow enough to achieve a wide lens area. This embodiment is preferred because the wider, centermost Fresnel tooth, if broken into multiple teeth, could result in multiple thin, and consequently, fragile and difficult to manufacture central (medial) Fresnel teeth.

In step 501, a first Fresnel tooth is modeled at the most lateral position (i.e., furthest from the optical center) along the Fresnel radial extent. A lateral color spot size (“spot size”) for that modeled first Fresnel tooth is then calculated.

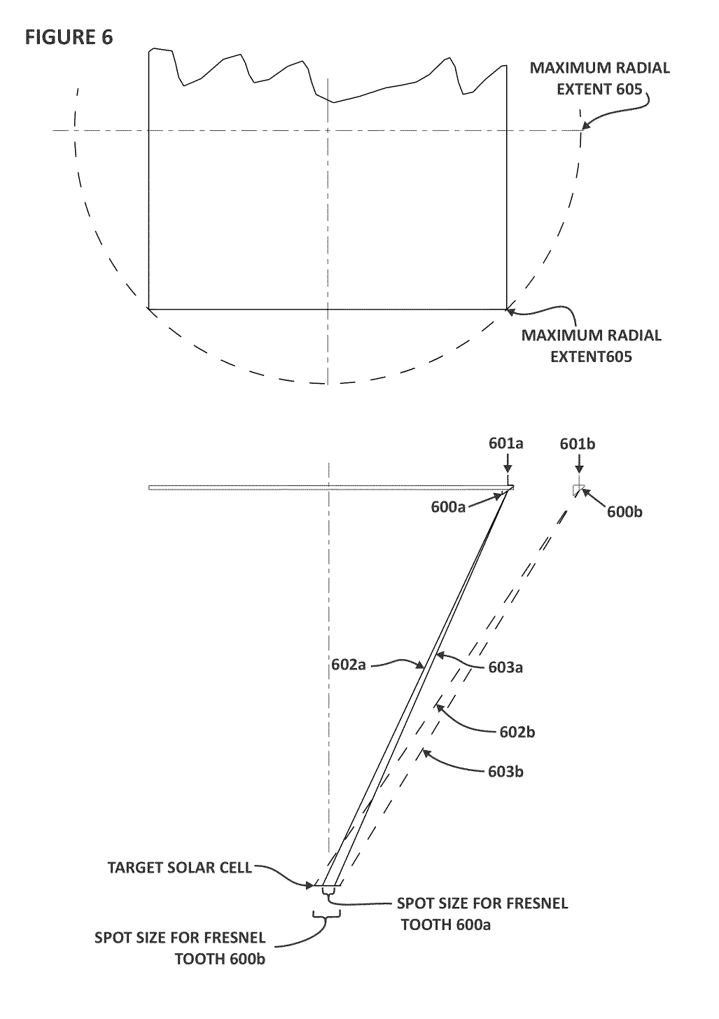

Although the maximum spot size can theoretically be equivalent to the width of a solar cell, spot size is typically minimized so as to restrict energy within a certain area of a target solar cell. Thus, an acceptable spot size is defined as a spot size that is smaller than the size of the target solar cell (that is, smaller than a maximum spot size for the target solar cell size). As illustrated in FIG. 6, a maximum spot size for a Fresnel tooth is determined by modeling incident light 601a normal to Fresnel tooth 600a, calculating an angle of refraction for a minimum wavelength of light (e.g., 435 nm) 602a, calculating an angle of refraction for a maximum wavelength of light (e.g., 1000 nm) 603a exiting Fresnel tooth 600a, and then modeling where the minimum and maximum wavelengths strike on a target solar cell. The maximum spot size is defined as the distance between those refracted light waves where they strike the surface plane of a target solar cell (i.e., at the focal distance). Likewise, a maximum spot size for a Fresnel tooth 600b is determined by modeling incident light 601b normal to Fresnel tooth 600b, calculating an angle of refraction for a minimum wavelength of light (e.g., 425 nm) 602b, calculating an angle of refraction for a maximum wavelength of light (e.g., 1000 nm) 603b exiting Fresnel tooth 600b, and then modeling where the minimum and maximum wavelengths strike on a target solar cell. Again, the maximum spot size is defined as the distance between those refracted light waves where they strike the surface plane of a target solar cell (i.e., at the plane at the focal distance). As shown in the figure, a more medial Fresnel tooth (e.g., Fresnel tooth 600a) yields a smaller spot size than does a more lateral Fresnel tooth (e.g., Fresnel tooth 600b). On a Fresnel lens, a maximum spot size occurs at the maximum radial extent 605 of the Fresnel concentrator region.

Once the maximum spot size is determined, an acceptable spot size can be defined. This step is important because chromatic aberration can cause the measured spot size to be larger than the target solar cell size, such that incoming light concentrated by the Fresnel would not be fully concentrated on the target solar cell and can make the system susceptible to damaging “walk-off” energy. In one embodiment, a maximum acceptable spot size is approximately 70% of a maximum spot size for the target solar cell size.

Returning now to FIG. 5, in step 502, the angle of the modeled first Fresnel tooth (i.e., the angle of the exit surface) is adjusted (to become either more acute or more obtuse) and/or the radius of the modeled first Fresnel tooth is modified (to make the Fresnel tooth wider or narrower) so as to obtain a maximum angle and/or the radius of the modeled first Fresnel tooth that can generate an acceptable spot size that is smaller than the size of the target solar cell. The width of a Fresnel tooth is governed by the desired tooth height.

Once an acceptable spot size is obtained, then, in step 503, the location of the modeled first Fresnel tooth is modified to center the spot of acceptable size on the target solar cell. For example, if a focal length of 140 mm and a 6.5 mm solar cell size are selected, a Fresnel radial extent of 84.5 mm will generate a spot size of 7.5 mm, which is too large for the target solar cell size. In this exemplar case, if the Fresnel radial extent is retracted (e.g., to approximately 80 mm), the spot can be centered on the target solar cell.

In step 504, a next Fresnel tooth medial to the first (immediately preceding) modeled Fresnel tooth is modeled. The acceptable spot size for that modeled next Fresnel tooth is then located. The radial extent effectively decreases as each more medial Fresnel tooth is modeled, so the magnitude of refraction is reduced—thereby producing a progressively smaller spot size as each more medial Fresnel tooth is modeled. Thus, for each modeled Fresnel tooth after the first modeled Fresnel tooth, the spot size is already optimized to an acceptable spot size.

In step 505, the angle of the modeled next Fresnel tooth (i.e., the angle of the exit surface) is adjusted (to become either more acute or more obtuse) so as to obtain an angle of the modeled next Fresnel tooth that allows the spot to be positioned as desired (e.g., centered on a target solar cell, or positioned somewhere off-center on the target solar cell). Because location of the modeled next Fresnel tooth is established by the modeled first Fresnel tooth, it is not necessary to modify the location of the next Fresnel tooth to position the spot of acceptable size.

In step 506, a determination is made as to whether the Fresnel concentrator region has been completed—that is, whether Fresnel teeth have been modeled along the radial extent of the working range of the Fresnel concentrator region. If, in step 506, a determination is made that the Fresnel concentrator region has not been completed, then the process returns to step 504 and another next Fresnel tooth is modeled and then optimized to control where the incident light strikes the target solar cell—but for a tooth medial to an immediately preceding modeled tooth. In a preferred embodiment, the process continues to loop back to step 504 until a most medial Fresnel tooth (at the optical center line) has been designed and the Fresnel concentrator region has been completed.

Gaussian first-order ray tracing (available through a variety of commercially available programs such as computer-assisted design programs, optics programs, etc.) is used to calculate Snell's law for multiple rays for each Fresnel tooth and to model and optimize performance of the Fresnel concentrator region optics as successive Fresnel teeth are designed and added. Embodiments of Fresnel concentrator region 102 can be manufactured with any desired number of teeth, but is preferably designed with 11 teeth for a tooled silicone TIR hybrid concentrator 101 optimized for a 5.5 mm solar cell.

If, in step 506, a determination is made that the working range of Fresnel concentrator region 102 has been completed, then the process of designing TIR concentrator region 103 is initiated. One embodiment of a method of designing a TIR concentrator region is diagrammed in the flowchart of FIG. 7.

The maximum extent of Fresnel functionality (i.e., a most lateral functional position along the radial extent of Fresnel concentrator region 102 which preferably corresponds to a most lateral Fresnel tooth) is a general starting point for building a TIR concentrator region that is later refined later to optimize solar concentration. For example, with a 6.5 mm solar cell, a TIR concentrator region begins approximately 68 mm from an optical center of a Fresnel concentrator region. Where a cutoff transition between Fresnel technology and TIR technology occurs is a function of the F-number. For a given lens diameter, a lower F-number (i.e., a shorter focal length) restricts the working area of Fresnel technology to a smaller proportion of the area of the TIR hybrid concentrator while increasing the working area of TIR technology within the TIR hybrid concentrator. That is, a shorter focal length will move the cutoff transition closer to the optical center of the TIR hybrid concentrator. Using a shorter focal length allows better spot focusing of a TIR concentrator region (i.e., light is less diffuse and more tightly focused on a solar cell) than a standard Fresnel lens and enables a thinner HCPV module (with consequent reductions in manufacturing, deployment, and installation costs of HCPV modules).

A TIR hybrid concentrator is designed by creating a first TIR feature immediately adjacent to a Fresnel concentrator region, then designing an adjacent second TIR feature which is located more laterally from the optical center of the first TIR feature, then designing an adjacent third TIR feature which is located more laterally from the second TIR feature, and so on. This process continues feature by feature until a target solar concentration can be achieved.

An initial design of each TIR feature 105 is a generic feature with linear edges shaped as in FIG. 4(a). The size of the generic feature is tooling and material-dependent. As an example, the first TIR elements tend to have a shallow slope of reflector surface 402. Thus, the size of entry surface 401 (e.g., narrow or short length) combined with the shallow slope of reflector surface 402 can result in tall TIR features. This phenomenon can be mitigated by reducing the size of entry surface 401 (i.e., making TIR feature 105 narrower) to achieve the best system performance. The generic feature works for a widest range of target solar cell sizes and target concentrations. Each TIR feature is then refined. More specifically, a first-order Gaussian TIR feature is modeled and then tuned for concentration, spot size, and spot localization by modifying (1) the slope of reflector surface 402 relative to normal; and/or (2) the slope of emitting surface 404 (which effectively changes α); and/or (3) the radius of reflector surface 402 and/or the radius of emitting surface 404. In a preferred embodiment, geometric parameters of TIR features 105 are optimized to maximize energy incident at interface S (i.e., on a detector).

A method of designing a TIR concentrator region 103 of a TIR hybrid concentrator 101 according to one embodiment will be described with reference to the both the flowchart shown in FIG. 7 and generic TIR feature 105 of FIGS. 4(a) and (b).

Referring first to FIG. 4(a), a design goal at interface Q in one embodiment is to minimize θ₃ (the angle of incidence as light ray B travelling from reflector surface 402 strikes emitting surface 404) and θ₁ (the angle of refraction as light ray B exits TIR feature 105 through emitting surface 404) by maximizing α (the slope of emitting surface 404) in order to reduce chromatic aberrations, reduce spot size, and optimize cell irradiance. Maximizing α, however, is achieved by increasing the angle of incidence (θᵢ) at interface Q. Thus, the degree to which a can be maximized is a trade-off limited by a necessary condition for total internal reflection that θᵢ cannot exceed θ_{c}. Furthermore, as θᵢ increases, the overall height of TIR feature 105 increases—which can negatively impact manufacturability of the concentrator optic (e.g., increased cost of materials and tooling). Additionally, increasing θᵢ can change direction of the incident light too much, thereby causing the light to miss a target solar cell.

Referring now to FIG. 7, in step 701, the angle of reflector surface 402 is modified so that light incident on reflector surface 402 (i.e., Interface Q) experiences total internal reflection and is reflected to travel through emitting surface 404 (i.e., interface R) at an angle that focuses the light to an acceptable spot located on a target solar cell (i.e., Interface S). Critically, the angle of incidence of light striking reflector surface 402 must equal the angle of reflection off reflector surface 402. As the angle of reflector surface 402 is modified, Snell's law for multiple rays exiting emitting surface 404 is applied to calculate angles of incidence to keep energy focused on the detector (e.g., target solar cell).

The purpose of changing the angle of reflector surface 402 is primarily to re-direct light to strike a detector (e.g., a target solar cell) at a desired spot or in a desired area, and secondarily, to focus that light on the target solar cell. Importantly, changing the angle of reflector surface 402 does not introduce chromatic aberration into the TIR concentrator system. In one embodiment, reflector surface 402 comprises an angle of approximately 45°.

In step 702, emitting surface 404 is modified to obtain a maximum angle of emitting surface 404 (e.g., a minimized θ₃) that can generate an acceptable lateral color spot size (“spot size”) with minimal chromatic aberration for generic feature 105. Emitting surface 404 can be modified by changing its slope (i.e., changing α, changing θ₁, and/or changing θ₃) and/or its shape. Changing the slope of emitting surface 404 reduces the degree of refraction that light rays experience when exiting TIR feature 105, and thus determines whether energy strikes a detector (e.g., target solar cell)—and where energy strikes on the surface of the target solar cell. Snell's law for multiple rays is applied to calculate angles of incidence to keep energy focused on the detector (e.g., target solar cell).

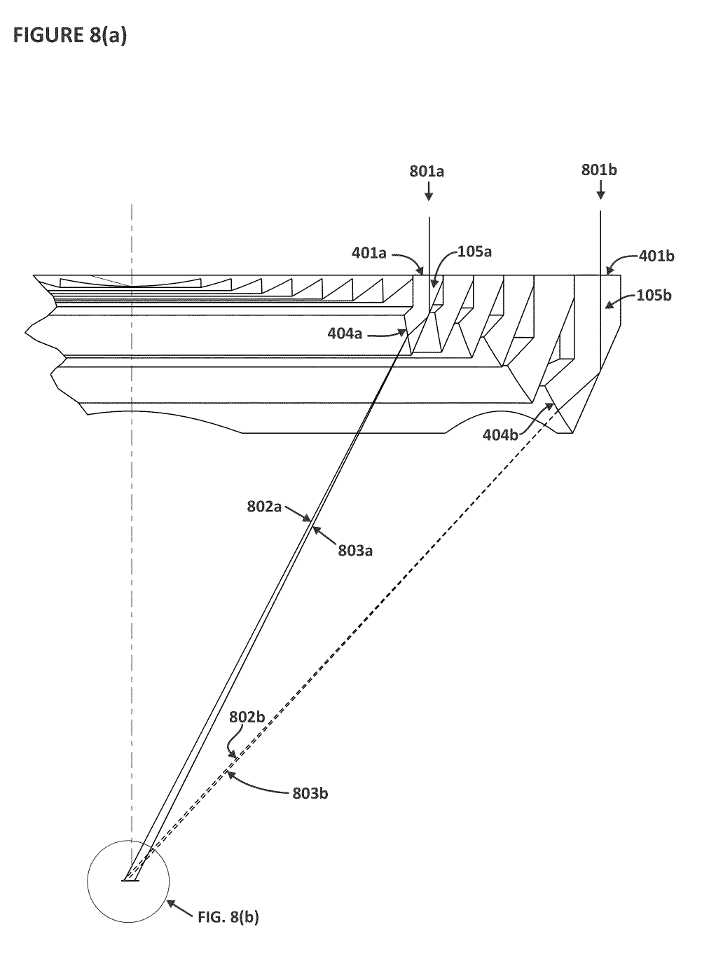

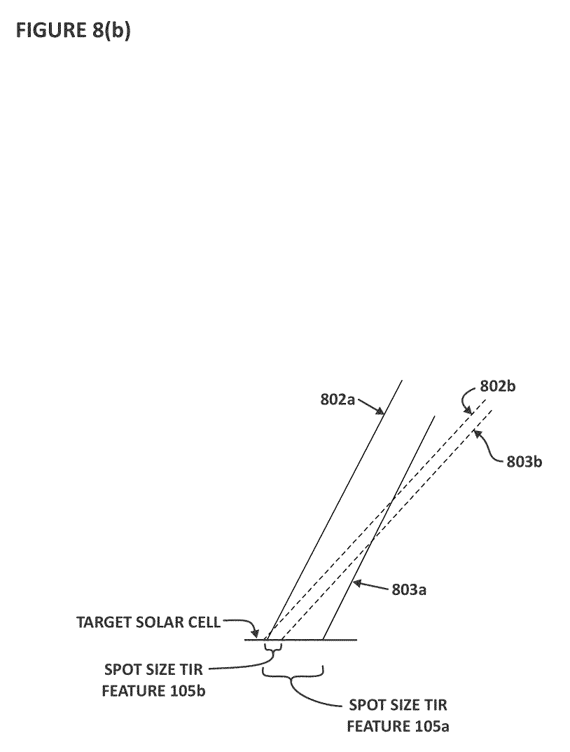

Although the maximum spot size can theoretically be equivalent to the width of a solar cell, spot size is typically minimized so as to restrict energy within a certain area of a solar cell. Thus, an acceptable spot size is defined as a spot size than is smaller than the size of the target solar cell (that is, smaller than a maximum spot size for the target solar cell size). As illustrated in FIGS. 8(a) and (b), a maximum spot size for a medial TIR feature 105a is determined by modeling incident light 801a normal to entry surface 401a, calculating an angle of refraction for a minimum wavelength of light (e.g., 425 nm) 802a, calculating an angle of refraction for a maximum wavelength of light (e.g., 1000 nm) 803a exiting TIR feature 105a through emitting surface 404a, and then modeling where the minimum and maximum wavelengths strike on a target solar cell. The maximum spot size is defined as the distance between those refracted light waves where they strike the surface plane of a target solar cell (i.e., at the plane at the focal distance). Likewise, a maximum spot size for a lateral TIR feature 105b is determined by modeling incident light 801b normal to entry surface 401b, calculating an angle of refraction for a minimum wavelength of light (e.g., 435 nm) 802b, calculating an angle of refraction for a maximum wavelength of light (e.g., 1000 nm) 803b exiting TIR feature 105b through emitting surface 404b, and then modeling where the minimum and maximum wavelengths strike on a target solar cell. Again, the maximum spot size is defined as the distance between those refracted light waves where they strike the surface plane of a target solar cell (i.e., at the plane at the focal distance). As shown in the figure, a more medial TIR feature (e.g., TIR feature 105a) yields a larger spot size than does a more lateral TIR feature (e.g., TIR feature 105b).

Once the maximum spot size is determined, an acceptable spot size can be defined. In one embodiment, a maximum acceptable spot size is approximately 70% of a maximum spot size for the target solar cell size.

Returning again to FIG. 7, θ₃ is the most significant variable that introduces chromatic aberration into TIR-mediated concentration. Thus, one design goal is to decrease θ₃ (the angle of incidence on emitting surface 404) or the more sensitive θ₁ (the angle of refraction from emitting surface 404, which co-varies with θ₃), preferably to approach zero. In practice, it can be easier to manipulate a itself to minimize θ₃- or even change the dimensions of undercut surface 403 to indirectly minimize θ₃. In theory, driving θ₃ to zero (e.g., by maximizing α) would eliminate chromatic aberration. In practice, however, as discussed elsewhere herein, a cannot always be maximized because increasing α can adversely affect where the spot is located and therefore require a change of slope in reflector surface 402 which simultaneously increases the height of TIR feature 105 (and negatively impacts manufacturability). Thus, α or θ₃ can be modified such that the angle of emitting surface 404 can be optimized to generate an acceptable spot size and spot location for generic feature 105.

Another consequence of modifying α is that undercut surface 403 can change in length, becoming either longer or shorter by, in some embodiments, an appreciable amount. Thus, modifying the length of undercut surface 403 (via modifying α) can be useful to accommodate adjacent TIR features 105 (e.g., to minimize shadowing), or to reduce the amount of optical material needed for TIR features. Regardless of how α is modified, the angle of undercut surface 403 remains static (since it is determined by and parallel to a most lateral light ray C which is reflected from a most superior position of the angled portion of reflector surface 402 to exit emitting surface 404).

Emitting surface 404 and reflector surface 402 can be non-linear (e.g., s-shaped, spherical, aspheric, freeform, conical, etc.). If one or both of these surfaces depart from linear, modification of these surfaces to optimize tuning of TIR features becomes more complex in that the shapes of emitting surface 404 and reflector surface 402 determine how many variables are available to modify. For example, if emitting surface 404 is a 3^{rd} order aspheric surface, TIR feature can then be tuned for concentration, spot size, and spot localization by modifying (1) the slope of emitting surface 404 relative to normal (which effectively changes α); and/or (2) the slope of reflector surface 402; and/or (3) the radius of reflector surface 402; and/or (4) the radius of emitting surface 404; and/or (5) the conic constant of the emitting surface; and/or (6) aspheric coefficient 1; and/or (7) aspheric coefficient 2; and/or (8) aspheric coefficient 3.

Importantly, because the functions of emitting surface 404 and reflector surface 402 are interdependent, steps 701 and 702 can be performed in any order, and/or nearly simultaneously (i.e., emitting surface 404 and reflector surface 402 can be co-varied) to fine-tune TIR feature 105.

In step 703, a determination is made as to whether a previously designed adjacent (i.e., more medial) TIR feature 105 is shadowing the TIR feature currently being designed. One of skill in the art will recognize that this step is not performed for the first designed TIR feature 105. If currently-being-designed TIR feature 105 is shadowed by a previously designed adjacent TIR feature, then the process returns to steps 701 and 702 which are performed so as to optimize reflector surface 402 and emitting surface 404 to obtain an acceptable spot location and minimize chromatic aberration to the extent possible within the constraints of minimizing shadowing of currently-being-designed TIR feature 105 by a previously designed adjacent (i.e., more medial) TIR feature 105.

Steps 701 and 702 can be performed in an order different from that shown in FIG. 7. Furthermore, each step 701 and 702 can be iterated one or more times, before and/or after making the determination of step 703.

If in step 703, a determination is made that a previously designed adjacent (i.e., more medial) TIR feature 105 is not shadowed by a currently being designed TIR feature 105, then, in step 704, a determination is made whether the target concentration has been achieved. If a determination is made that a target concentration has not been achieved, then the process returns to step 701 to design another TIR feature 105. Because the extent (e.g., size and/or number) of TIR features is based on desired target concentration, the actual number of TIR features is not critical.

If, in step 704, a determination is made that the target concentration has been achieved, then, in step 705, a merit function is applied to fine-tune designed TIR features 105 to optimize energy from TIR concentrator region 103 incident at the detector (e.g. the target solar cell). Optical software suitable for design optimization of TIR features 105 is commercially available (e.g., ASAP® from Breault Research Organization, Inc.; Zemax from Radiant Zemax, LLC; LightTools® from Synopsys). These merit functions can optimize and fine-tune each TIR feature 105, then iterate the process until a best solution (e.g., maximal energy incident at the detector (e.g., the target solar cell) is achieved. Or, for uniformity, multiple TIR features 105 can be optimized at once.

A design goal is to minimize θ₃ throughout a TIR concentrator (or TIR concentrator region). As TIR features 105 become more lateral within a TIR concentrator (or TIR concentrator region), α increases and θ₃ decreases to more closely approach zero. That is, in more medial TIR features 105, a is smaller and θ₃ is bigger. Importantly, then, α and θ₃ (or θ₁) can be optimized for each feature independently. Applying a merit function to obtain a best solution for a TIR concentrator (or TIR concentrator region) allows all the TIR features 105 within a TIR concentrator (or TIR concentrator region) to be simultaneously optimized in light of the other TIR features 105.

As discussed elsewhere herein, a TIR hybrid concentrator can concentrate solar energy to levels too high for a detector (e.g., solar cell) to handle. Thus, a best solution need not be maximal concentration achievable. As an example, a merit function can be defined to minimize the peak irradiance on a target cell while maximizing the incident energy with another merit function operand defining the upper limit irradiance. Weighting factors are applied to all operands. Weighting can be modified to optimize the net output based on the target cell performance. For example, if irradiance is too high, cell efficiency can drop. Therefore, the maximum irradiance operand weight can be set high relative to other operands to insure the maximum irradiance is not violated.

TIR features can be modified as discussed with reference to FIG. 7 to generate a best solution. It is expressly contemplated that a best solution can also be differential localization of solar concentration across a target solar cell, same or near-same solar concentration across a target solar cell, or otherwise.

A design goal is one embodiment is to design a TIR feature as short as possible. A shorter TIR feature results in decreased manufacturing costs. More importantly, as a TIR features are designed medially to laterally within a TIR concentrator region, TIR features increase in size. More medial TIR features are necessarily shorter so as to not shadow more lateral TIR features. As reflector surface 402 becomes steeper, a TIR feature becomes shorter.

Thermal coefficients vary for different materials, and ambient temperature changes of 50° C. are common for HCPV. Computerized optimization algorithms can optimize TIR hybrid concentrator design given known temperatures of operation and thermal coefficients.

Current HCPV systems can concentrate energy to about 1000 suns, but not much more with reasonable focal lengths. Embodiments of a TIR hybrid concentrator as described herein are much more powerful and can concentrate light energy to a higher degree than can be handled by current solar cells. As future solar cells become more robust, a peak irradiance of 10,000 suns is easily possible. TIR concentrator optics can be used to spread energy across a solar cell to reduce peak irradiance at center and enhance off-center (“center-surround”) irradiance to achieve higher efficiencies than can be achieved by current Fresnel technologies. Embodiments of TIR concentrator optics described herein (unlike Fresnel optics) can be tuned to optimize energy generation by controlling both localization and magnitude of light energy on a solar cell. For example, by changing the shape of TIR features 105, TIR concentrator optics can be used to position energy at different spots on a solar cell to reduce peak irradiance in the center of the solar cell and more evenly distribute incident energy across the surface of a solar cell, and thereby increase the total output energy from the solar cell.

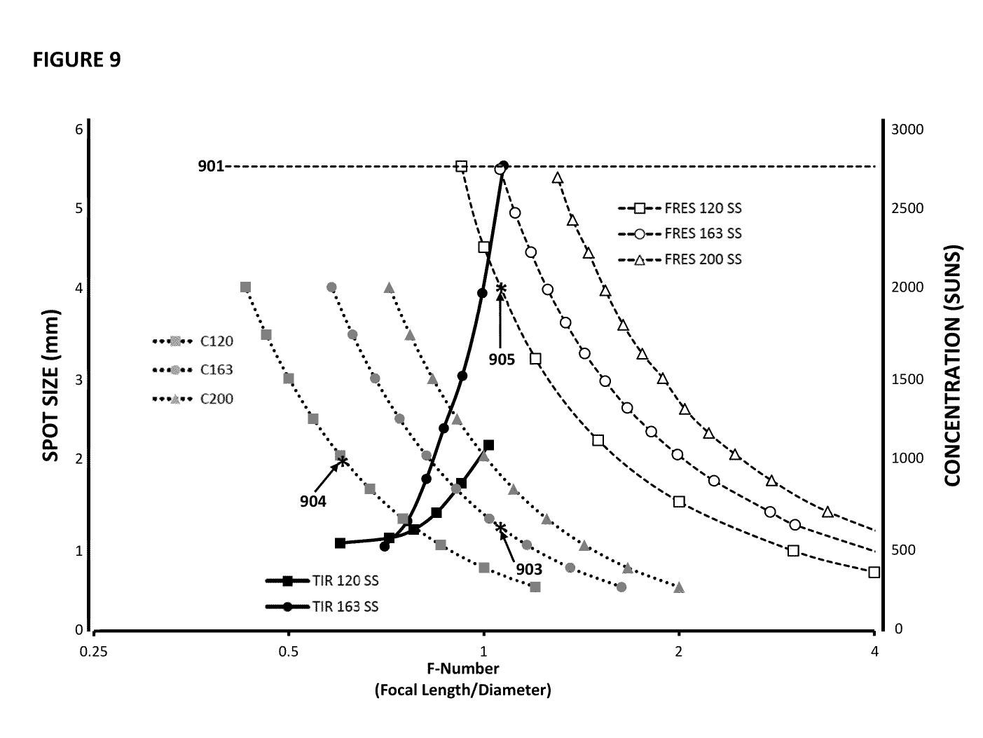

FIG. 9 is a scatter plot showing lateral color spot size (“spot size”) as a function of F-number (focal length/diameter) for a Fresnel concentrator region at focal lengths of 120, 163, and 200 mm and a TIR concentrator region at focal lengths of 120 and 163 mm. Spot size (e.g., the distance across a solar cell between short and long wavelengths) was determined using a practical range of wavelengths (425 nm and 1000 nm) seen in the conversion of solar energy. Solar concentration as a function of F-number is shown for focal lengths of 120 mm (C120), 163 mm (C163), and 200 mm (C200) with concentration (in suns) on the right vertical axis. Spot size as a function of F-number for a Fresnel concentrator with focal lengths of 120 mm (FRES 120 SS), 163 mm (FRES 163 SS), and 200 mm (FRES 200 SS) is shown by the 3 curves on the right side of the figure with spot size in mm on the left vertical axis. Spot size as a function of F-number for a TIR hybrid concentrator with focal lengths of 120 mm (TIR 120 SS) and 163 mm (TIR 163 SS) is shown by the 2 curves in the center of the figure. At N=1, the focal length is equal to the diameter of an optical lens. When N is greater than 1, the focal length is greater than the lens diameter, whereas when N is less than 1, the lens diameter is greater than the focal length. At N=2, the focal length is two times the diameter of the optics. Because energy is proportional to lens area, energy increases by the square of the radius of the lens. This is represented in FIG. 9 as one moves from right to left on the x-axis. As N decreases from 4 to 0.25, one is moving along the radius of the optics further from the optical center.

Given a solar cell size of 5.5 mm, a Fresnel lens operating at a 163 mm focal length can only achieve a maximum solar concentration of approximately 550-600 suns (as indicated by the point at which the curve for the spot size of a Fresnel lens operating at 163 mm focal length intersects line 901 (indicating a 5.5 mm solar cell), and a vertical line dropped from that intersection point intersects the concentration curve for a 163 mm focal length (C163) Fresnel lens at point 903. The vertical location of that intersection (point 903) is used with the right side vertical axis to determine the concentration (550-600 suns). In contrast, a TIR concentrator operating at a focal length of 120 mm can easily achieve about 1000 suns concentration with a solar cell size of 4.2 mm. A concentration of 1000 suns can be achieved at an F-number of N=0.6 (as indicated by the intersection at point 904 of a vertical line extended from TIR 120 SS curve at N=0.6 to concentration curve C120). For point 904, concentration can be read from the right side vertical axis to be approximately 1000 suns. Point 905 is the technology transfer point for a 5.5 mm spot size, the point at which TIR technology becomes more effective than the Fresnel technology. The spot size of the Fresnel concentrator region is the primary determinant of the technology transfer point. Concentrations greater than 1000 suns are possible by making a larger lens (which yields a lower F-number). Mechanical and physical limitations limit the achievable concentration. Concentrations of 2000 suns are easily achievable, but cannot yet be optimized because solar cell technologies are currently unable to support the irradiance with typical solar cell sizes. Notably, however, embodiments as described herein can achieve ultra-high concentrations with very small cell sizes. Thus, at F-numbers less than 1, TIR concentrator optics yield very high concentrations—much higher than can be generated by Fresnel concentrator optics. When Fresnel-mediated concentration and TIR-mediated concentration are combined in a TIR hybrid concentrator (not shown in FIG. 9), maximal achievable solar concentration is even greater as discussed elsewhere herein.

One problem with current solar concentration technologies is that a standard Fresnel lens with relatively large F-numbers (e.g., N>1.2) focuses energy well in the center of a solar cell, but is unable to effectively concentrate solar energy across center-surround areas of a solar cell. A TIR hybrid concentrator solves this problem by using Fresnel technology where it is strongest (i.e., at F-numbers above 1) and using TIR technology where it is strongest (i.e., at F-numbers below 1). This approach allows a greater area of a solar cell to be utilized for solar concentration and, consequently, yields quantifiably higher solar concentrations than have been achievable to date.

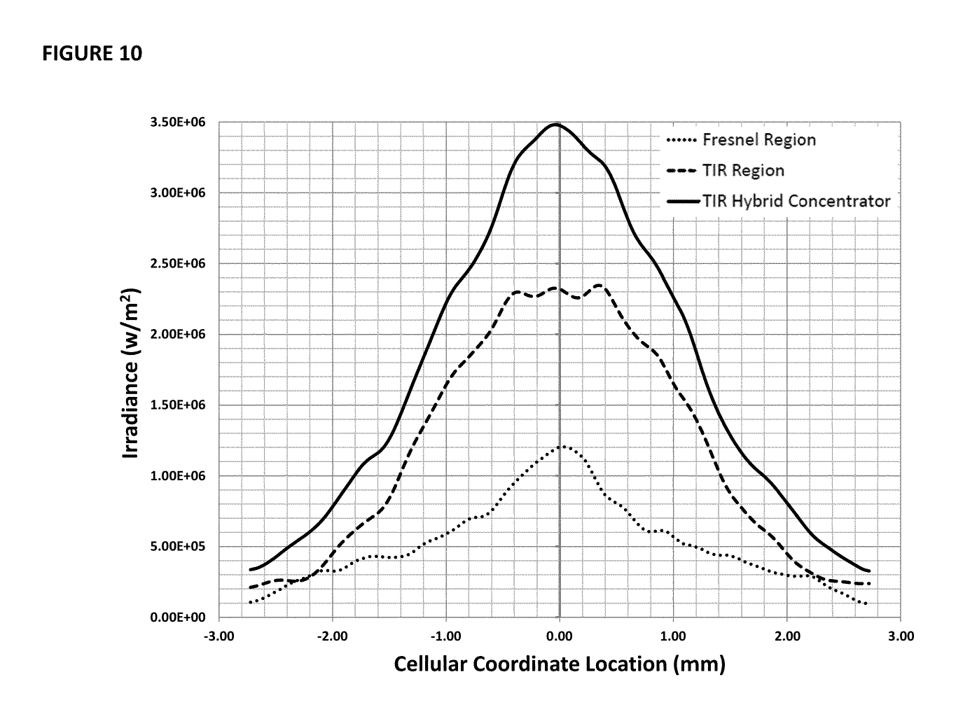

This advantage of TIR-mediated solar concentration is graphically illustrated in FIG. 10, which shows a scatter plot of modeled data for irradiance as a function of cellular coordinate location for a TIR hybrid concentrator as well as for its TIR concentrator region and Fresnel concentrator region according to one embodiment. In this figure, the x-axis represents the cellular coordinate location across the diameter of a 5.5 mm solar cell, with x=0 being the center of the solar cell (i.e., 2.5 mm from an edge of the solar cell). As shown, a Fresnel concentrator region with 8.8 W of energy incident on the target solar cell typically generates peak irradiance at the center of a solar cell on the order of 1.2×10⁶ W/m² with irradiance rapidly tailing off as distance from the center of the target solar cell increases. A TIR concentrator region with 18.1 W incident on the target solar cell generates a peak irradiance at the center of the target solar cell on the order of 2.3×10⁶ W/m² with irradiance falling slowly as distance from the center of the target solar cell increases. Although a TIR hybrid concentrator can generate a peak irradiance much higher than Fresnel-mediated or TIR-mediated technology alone (on the order of 3.5×10⁶ W/m²), the peak irradiance is low compared to the overall amount of energy incident on the target solar cell (approximately 27.3 W). In short, with a TIR hybrid concentrator, high irradiance can still be obtained from center-surround areas of a target solar cell—including from areas quite close to the edges of the target solar cell. In practical terms, this means that fewer solar cells are needed to obtain a desired energy output from an HCPV system.

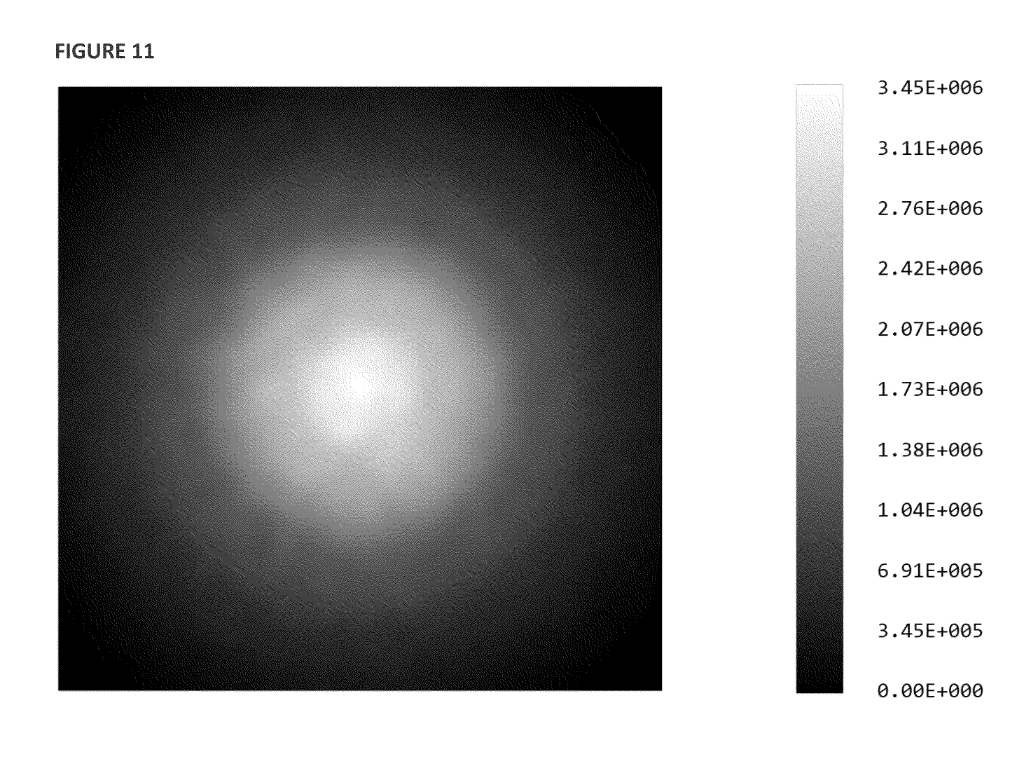

Another problem with current solar concentration technologies is that a Fresnel lens (with or without a secondary concentrator) requires large F-numbers to generate high solar concentration (e.g., 1000 suns or better). TIR concentrators, on the other hand, can achieve very high solar concentration and power densities with relatively low F-numbers (e.g., N<0.7). Thus, TIR-mediated solar concentration can be used in a smaller HCPV system to achieve a greater concentration than can be obtained using Fresnel technology at a similar focal length. This advantage of TIR-mediated solar concentration is graphically illustrated in FIGS. 11-17 below, which show modeled power distribution maps of TIR-mediated and Fresnel-mediated solar concentration.

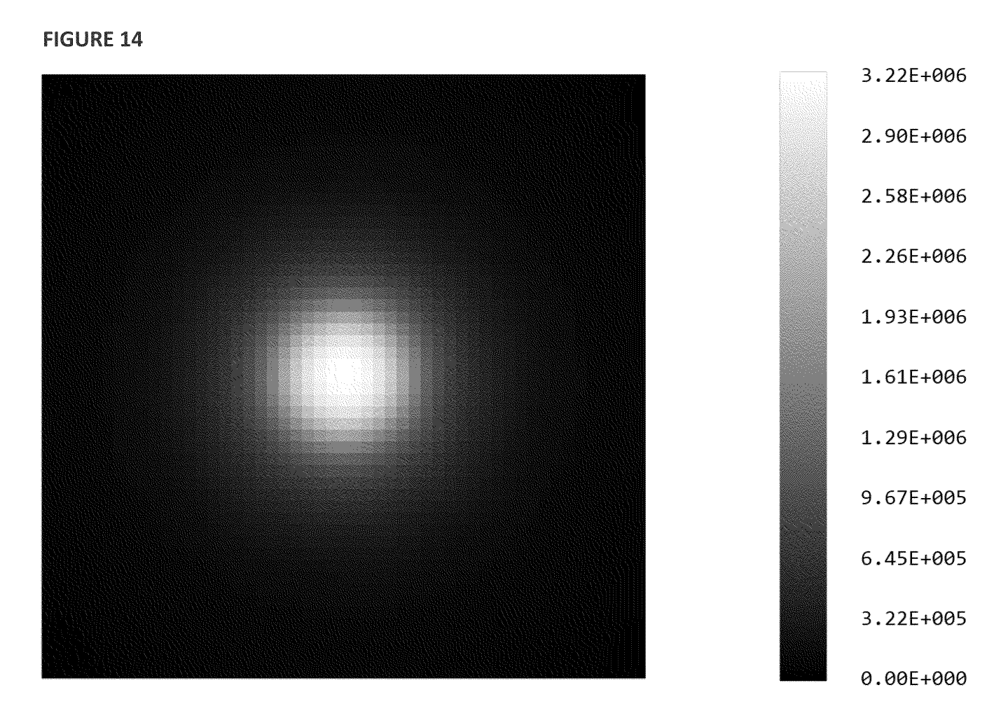

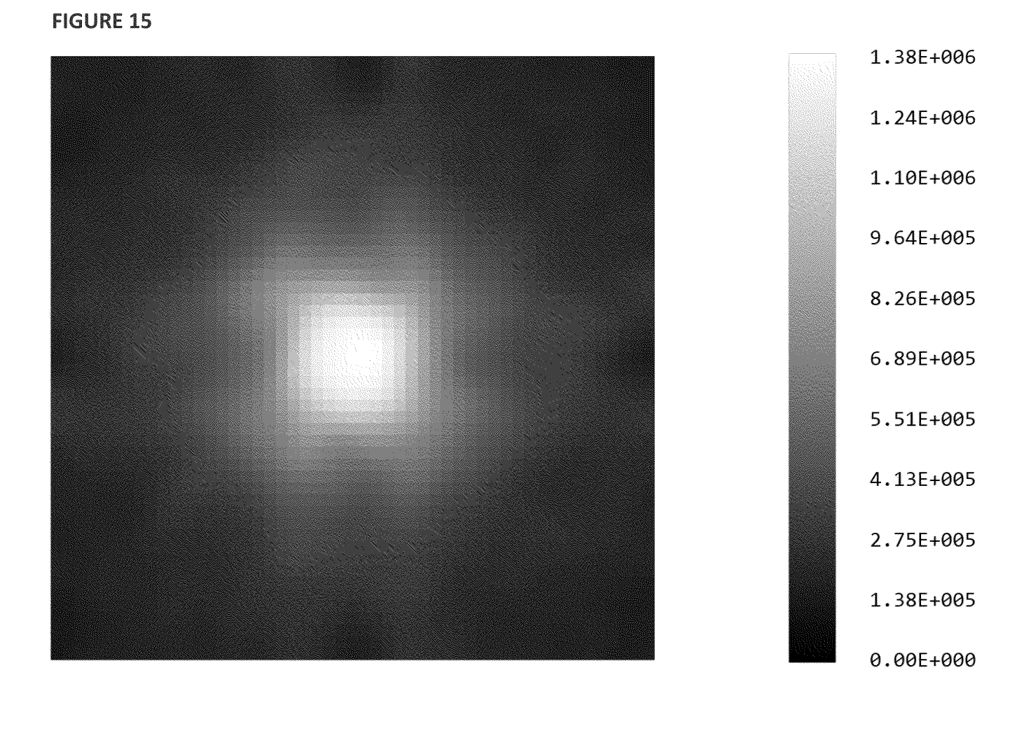

FIG. 11 is a top-down view of a modeled power distribution map showing a two-dimensional power distribution incident on of a 5.5 mm solar cell receiving light passed through a TIR hybrid concentrator with a focal length of 120 mm and a geometrical concentration of 1000 suns according to one embodiment. Scale units are shown in W/m². Energy input is standardized to a DNI of 1000 W/m². Peak irradiance in the center of the solar cell is 3.45×10⁶ W/m². Power incident on the TIR hybrid concentrator (Φₒ) is 30.27 W, yielding an incident energy density (M) of 904 W/m², a total power incident on cell (Φ_{optical}) of 27.35 W and an optical efficiency (η) of 0.904 (i.e., 90.4%). Another useful metric for quantitative comparison of HCPV receivers is power density (i.e., the power over the volume of the system). A hybrid TIR concentrator with an F-number of 0.6 achieves a power density of 7.533 W/L. An equivalent-sized Fresnel system achieves a power density of 6.35 W/L (see, e.g., discussion regarding FIGS. 14 and 15). As discussed elsewhere herein, one major advantage of a TIR hybrid concentrator is that it uses a Fresnel concentrator region to focus energy in a center region of a solar cell while simultaneously using a TIR concentrator region to focus energy in a center-surround region of the solar cell. Thus, energy is captured across a wide surface of the solar cell (rather than primarily from the center of a solar cell)—and at a high level of efficiency (e.g., approximately 90%) which approaches a theoretical maximum achievable optical efficiency.

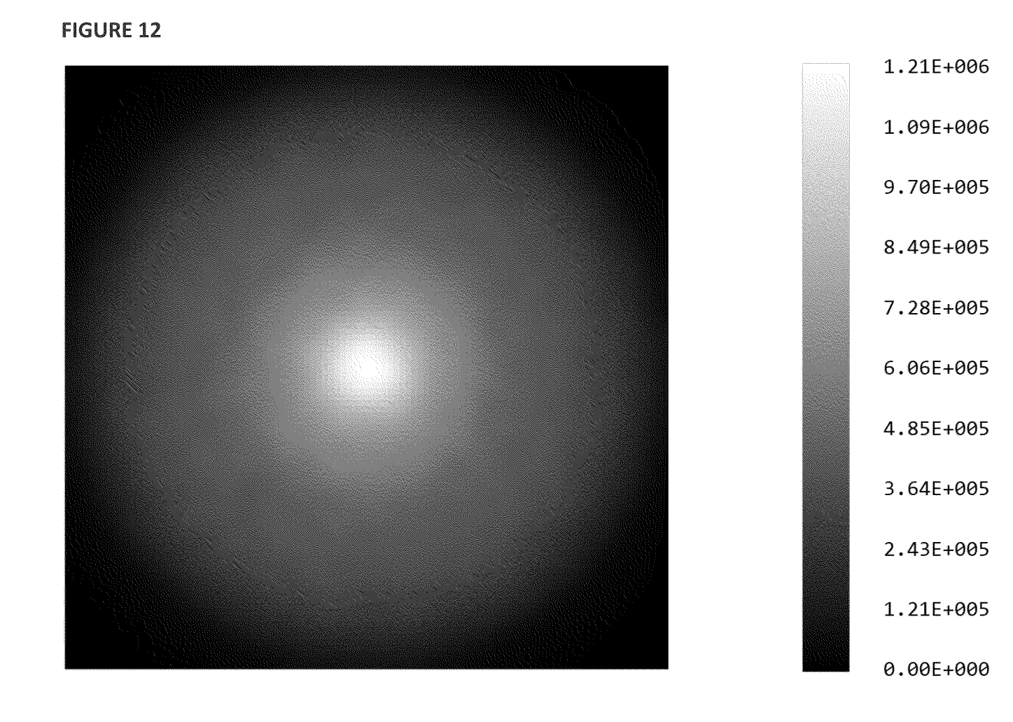

FIG. 12 is a top-down view of a modeled power distribution map showing a two-dimensional power distribution incident on a 5.5 mm solar cell receiving light passed through the center of a Fresnel concentrator region of a TIR hybrid concentrator with a focal length of 120 mm and a geometrical concentration of 326 suns according to one embodiment. A target concentration of 326 suns is obtained (rather than 1000 suns) because the Fresnel concentrator region in this case comprises 32.6% of the lens area of the TIR hybrid concentrator. Scale units are shown in W/m². Energy input is standardized to a DNI of 1000 W/m². Peak irradiance in the center of the solar cell is 1.21×10⁶ W/m². Power incident on the Fresnel concentrator region (Φₒ) is 9.85 W, yielding an incident energy density (M) of 894 W/m², a total incident power (Φ_{optical}) of 8.81 W, and an optical efficiency (η) of 0.894 (i.e., 89.4%). A TIR hybrid concentrator a Fresnel concentrator region to focus energy primarily where the Fresnel efficiency is highest: on a center region of the solar cell. Although a Fresnel concentrator region can contribute to focusing solar energy on center-surround regions of the solar cell, using a TIR concentrator region encircling a Fresnel concentrator region yields a higher optical efficiency at a shorter focal length than is obtainable with a standard Fresnel lens alone—or even with a Fresnel concentrator region alone. Optical efficiency per cell on the center region of the solar cell can be increased somewhat over that of a standard Fresnel lens at the same focal length—that is, because the Fresnel concentrator region can operate at a larger F-number than a standard Fresnel lens, the Fresnel concentrator region can achieve close to a theoretical maximal optical efficiency at a much shorter focal length than is possible using a standard Fresnel lens to concentrate solar energy on an entire surface of a target solar cell.

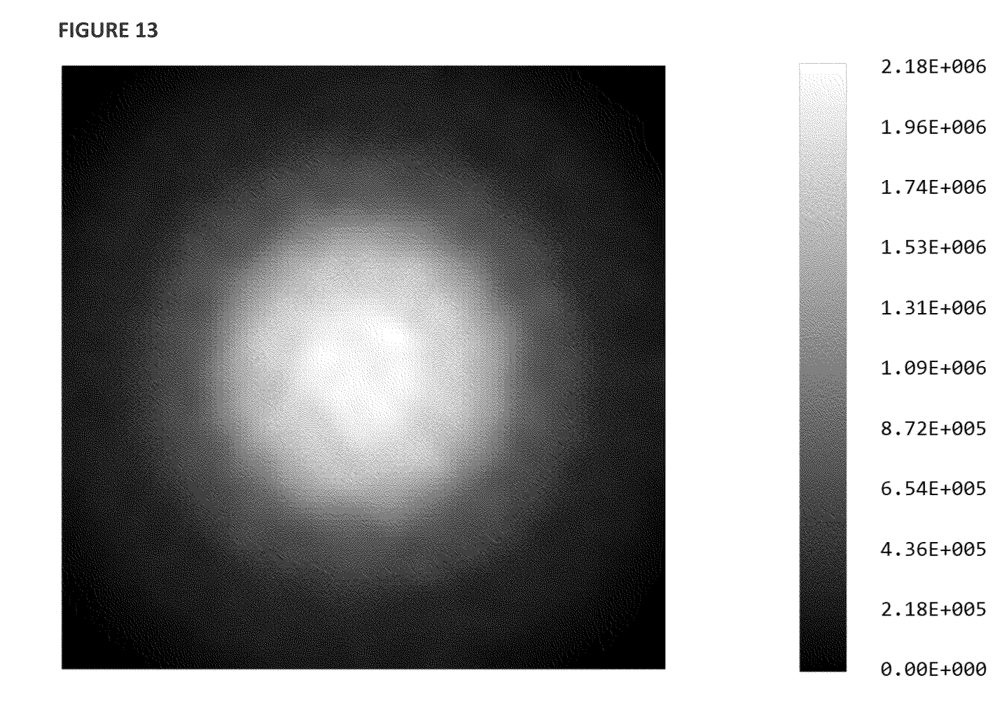

FIG. 13 is a top-down view of a modeled power distribution map showing a two-dimensional power distribution (W/m²) incident on a 5.5 mm solar cell receiving light passed through a TIR concentrator region of a TIR hybrid concentrator with a focal length of 120 mm and a geometrical concentration of 674 suns according to one embodiment. A target concentration of 674 suns is obtained rather than 1000 suns because the TIR concentrator region in this case comprises 67.4% of the lens area of the TIR hybrid concentrator. Scale units are shown in W/m². Energy input is standardized to a DNI of 1000 W/m². Peak irradiance in the center of the solar cell is 2.18×10⁶ W/m². Power incident on the TIR concentrator region (Φₒ) is 20.418 W, yielding an incident energy density (M) of 887 W/m², a total incident power (Φ_{optical}) of 18.12 W and an optical efficiency (η) of 0.887 (i.e., 88.7%). Because of the unique performance attributes of a TIR concentrator region, spot size shrinks as the F-number gets smaller, allowing a TIR hybrid concentrator to focus energy where the Fresnel concentrator optics is ineffective: a center-surround region of a solar cell. Optical efficiency per cell on the center-surround region can be increased greatly (e.g., to approximately 88-90%) over performance of Fresnel optics in that center-surround region—again, close to a theoretical maximal energy conversion efficiency.

A standard Fresnel lens is not capable of achieving low F-number solutions such as high concentration (e.g., 1000 suns) at a focal length of 120 mm. A standard Fresnel lens can be used at a short focal length (e.g., 120 mm), but only with a concomitant tradeoff in concentration. FIG. 14 shows a top-down view of a modeled two-dimensional power distribution incident on a 5.5 mm solar cell receiving light passed through a Fresnel lens (without a secondary optics) with an N=0.97, a focal length of 120 mm, and a geometrical concentration of 425 suns. Scale units are shown in W/m². Energy input is standardized to a DNI of 1000 W/m². Peak irradiance in the center of the solar cell is 3.22×10⁶ W/m². Power incident on the Fresnel lens (Φₒ) is 12.868 W, yielding an incident energy density (M) of 763 W/m², a total incident power (Φ_{optical}) of 9.82 W and an optical efficiency (η) of 0.763 (i.e., 76.3%). Power density is 6.93 W/L. As can be seen in the figure, a shorter focal length restricts how much solar concentration can be achieved. At an F-number of N=0.97 and focal length of 120 mm, solar concentration maxes out at 425 suns—well below a desirable 1000 suns concentration. Because power density is therefore very low, more solar cells are needed per HCPV, thereby increasing cost of an HCPV system.

Addition of a secondary optics to a standard Fresnel lens does not overcome the limitation that a standard Fresnel lens is not capable of achieving a high concentration (e.g., 1000 suns) with low F-numbers. Nevertheless, a standard Fresnel lens with a secondary optics can achieve at higher power density at a short focal length (e.g., 120 mm) than a standard Fresnel lens alone—but again, at a lower solar concentration. FIG. 15 is a top-down view of a modeled power distribution map showing a two-dimensional power distribution incident on a 5.5 mm solar cell receiving light passed through a standard Fresnel lens (with a secondary optics) with a focal length of 120 mm and a geometrical concentration of 425 suns. Scale units are shown in W/m². Energy input is standardized to a DNI of 1000 W/m². Peak irradiance in the center of the solar cell is 1.38×10⁶ W/m². Power incident on the Fresnel lens (Φₒ) is 12.868 W, yielding an incident energy density (M) of 832 W/m², a total incident power (Φ_{optical}) of 10.77 W and an optical efficiency (η) of 0.832 (i.e., 83.2%). Power density is 6.930 W/L. As can be seen in the figure, use of a secondary optics focuses energy on some center-surround regions, but much of the solar cell remains underutilized, which is reflected in the low power density (and increasing HCPV system costs).

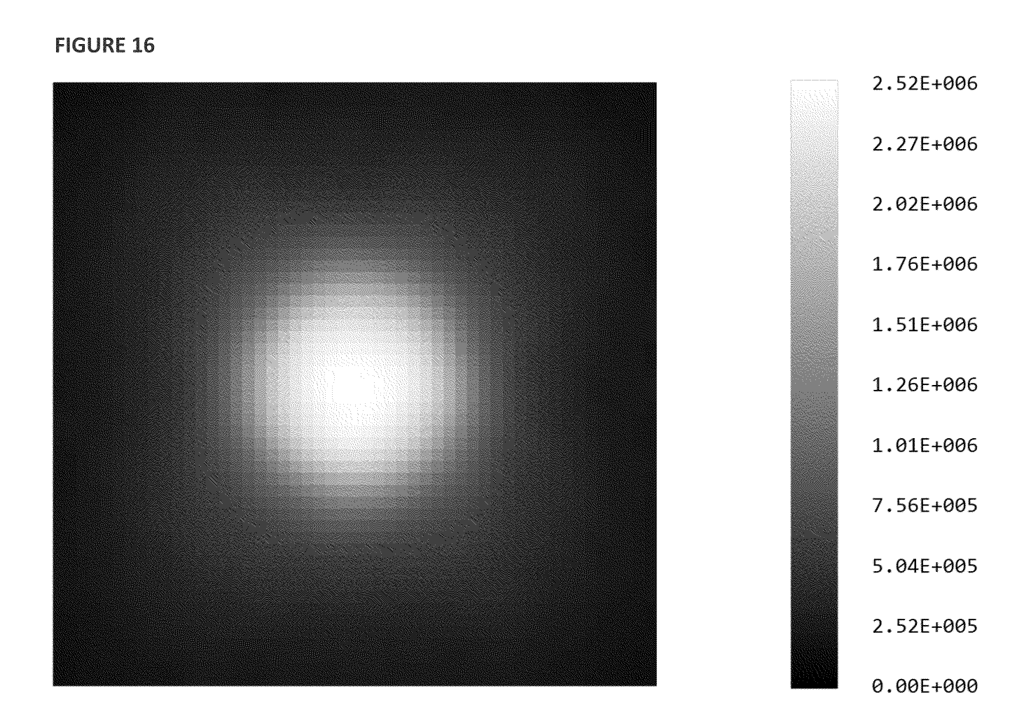

A standard Fresnel lens can be used to obtain a high solar concentration (e.g., 1000 suns), but requires a large F-number, e.g., greater than 1.0 or higher. Referring now to FIG. 16, a top-down view of a modeled two-dimensional power distribution incident on a 5.5 mm solar cell receiving light passed through a Fresnel lens (without a secondary optics) with an F-number of N=1.0, a focal length of 200 mm, and a geometrical concentration of 1000 suns. Scale units are shown in W/m². Energy input is standardized to a DNI of 1000 W/m². Peak irradiance in the center of the solar cell is 2.52×10⁶ W/m². Power incident on the Fresnel lens (Φₒ) is 30.27 W, yielding an incident energy density (M) of 833 W/m², a total incident power (Φ_{optical}) of 25.2 W and an optical efficiency (η) of 0.833 (i.e., 83.3%). Power density is 4.165 W/L. As can be seen in the figure, while a standard Fresnel lens alone can generate a high solar concentration (1000 suns) at large F-numbers (e.g., N>1) with a long focal length (200 mm), most of that concentrated energy strikes the center of a solar cell while center-surround regions of a solar cell are underutilized, which increases cost per HCPV system. One drawback of using a longer focal length to achieve a desired concentration of 1000 suns is that the size of an HCPV system must be increased to accommodate the long focal length, and power density is correspondingly lower than desirable, with a concomitant increase in manufacturing, deployment, and installation costs (in both dollars and real estate), again increasing cost per HCPV system.

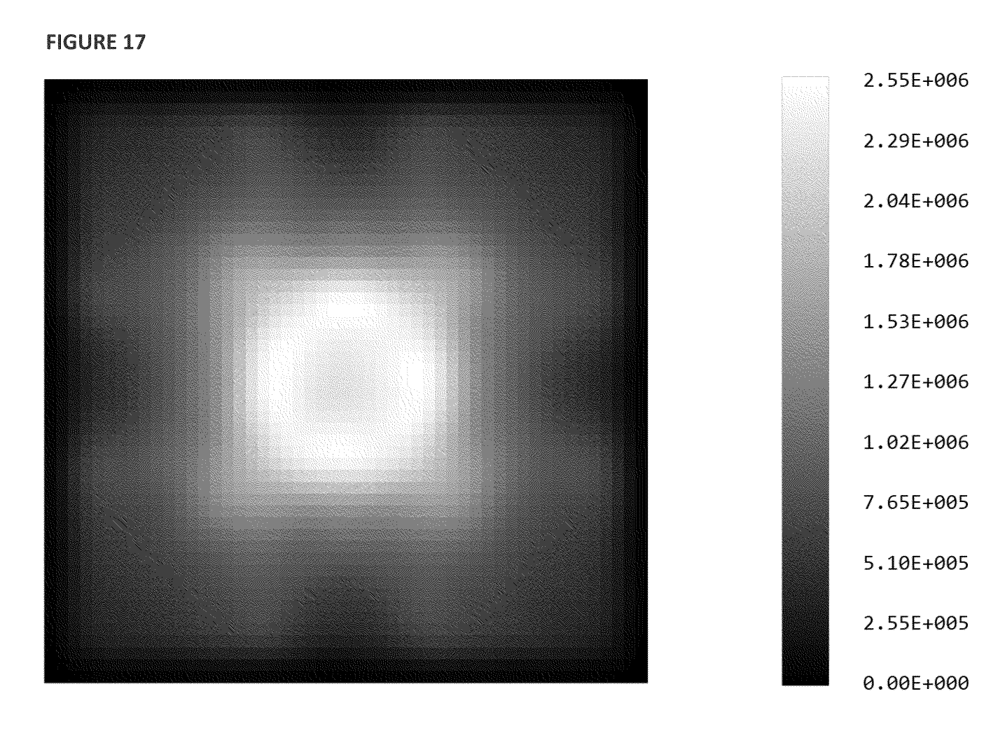

Adding a secondary optics to a Fresnel lens operating at a long focal length (e.g., 200 mm) can reduce peak irradiance and increase uniformity—but likely not enough to overcome the necessity of a larger HCPV system. FIG. 17 is a top-down view of a modeled power distribution map showing a two-dimensional power distribution incident on a 5.5 mm solar cell receiving light passed through a standard Fresnel lens (with a secondary optics) with a focal length of 200 mm and a geometrical concentration of 1000 suns. Scale units are shown in W/m². Energy input is standardized to a DNI of 1000 W/m². Peak irradiance in the center of the solar cell is 2.55×10⁶ W/m². Power incident on the Fresnel lens (Φₒ) is 30.27 W, yielding an incident energy density (M) of 855 W/m², a total incident power (Φ_{optical}) of 25.88 W and an optical efficiency (η) of 0.855 (i.e., 85.5%). Power density is 4.2575 W/L. As can be seen in the figure, use of a standard Fresnel lens with a secondary optics can focus solar energy across a greater region of a solar cell, but hot spots of irradiation and cold spots of non-irradiation remain. Thus, power density, while greater than obtainable with a Fresnel lens alone, remains lower than desirable despite a longer focal length (e.g., to 200 mm) and HCPV system manufacturing, deployment, and installation costs remain high.

In short, a TIR hybrid concentrator offers an advantage of generating a greatly enhanced power density (e.g., 7.533 W/L at 120 mm with 1000 sun concentration yielding 27.35 W as in FIG. 11) as compared to a standard Fresnel lens used at a same focal length either with a secondary optics (e.g., 6.93 W/L at 120 mm with 425 sun concentration yielding 9.82 W as in FIG. 15) or without a secondary optics (e.g., 6.35 W/L at 120 mm with 425 sun concentration as in FIG. 14), as well as compared to a standard Fresnel lens used at greater focal lengths either with a secondary optics (e.g., 4.2575 W/L at 200 mm as in FIG. 17) or without a secondary optics (e.g., 4.165 W/L at 200 mm as in FIG. 16). To achieve power densities for Fresnel-mediated solar concentration at all close to those achieved with TIR-mediated solar concentration, many more solar receivers must be used. TIR-mediated solar concentration then, allows an HCPV system to be smaller (because of the ability to perform well at lower F-numbers) and to use fewer solar cells per HCPV system (because more energy is generated from single solar cells) than is possible with standard Fresnel-mediated solar concentration. These advantages translate to lower costs of manufacture, deployment, and installation of HCPV systems.

As discussed elsewhere herein, embodiments of a TIR hybrid concentrator can be tuned to provide high solar concentration, which results in greater power output from a HCPV system. In one embodiment, a TIR hybrid concentrator can be tuned by increasing the contribution of TIR-mediated optical concentration relative to Fresnel-mediated optical concentration. Optical parameters of a modeled TIR hybrid concentrator with a lens radius of 98 mm and 120 mm (each with a 56 mm Fresnel concentrator region radius) concentrating light on a 5.5 mm solar cell at a focal length of 120 mm are presented in Table I.

TABLE I
Optical Parameters of Modeled TIR Hybrid Concentrator Embodiments
(for 5.5 mm solar cell and 56 mm Fresnel radius)

| Parameter | Equation | 98 mm radius | | 120 mm radius | |
|---|---|---|---|---|---|
| DNI | E = 1000 W/m² | 1000 | W/m² | 1000 | W/m² |
| Optical Area | A_{optical} = (π)(lens radius)² | 301.719 | cm² | 452.389 | cm² |
| Power incident | Φ_{optical} = (E)(A_{optical}) | 30.172 | W | 45.239 | W |
| on lens | | | | | |
| Optical Net | Φₙ = (η_{optical})(Φ)(A_{optical}) | 27.367 | W | 40.750 | W |
| Power | | | | | |
| Optical Efficiency | η_{optical} = (Φₙ)/(Φ_{optical}) | 0.907 | | 0.901 | |
| Fresnel Area | A_{fresnel} = (π)(Fresnel radius)² | 99 | cm² | 99 | cm² |
| TIR Area | A_{TIR} = A_{optical} − A_{fresnel} | 203 | cm² | 354 | cm² |
| Technology Ratio | Ratio_{tech} = A_{TIR}/A_{fresnal} | 2.063 | | 3.592 | |
| (TIR:Fresnel) | | | | | |
| Concentration | A_{optical}/(chip diameter)² | 997 | suns | 1496 | suns |
| (suns) | | | | | |

As shown in the table, when the radius of the TIR concentrator region is increased by a small amount (i.e., less than one inch—from 42 mm to 64 mm), the technology ratio increases from 2 (i.e., twice as much real estate of the lens devoted to TIR-mediated optical concentration as to Fresnel-mediated optical concentration) to 3.5 (i.e., three and a half times as much real estate of the lens devoted to TIR-mediated optical concentration as to Fresnel-mediated optical concentration), and optical power is almost doubled (from 27.3 to 40.7 W). That small increase in the radius of the TIR concentrator region yields a 500 sun increase in solar concentration (997 suns to 1496 suns) with little effect on HCPV system size.

In direct contrast to a standard Fresnel lens (which suffers from increasing chromatic aberration as lens radius increases), chromatic aberration decreases as the radius of a TIR hybrid concentrator increases—even at high solar concentrations (e.g., greater than 1000 suns). Thus, a larger lens can be used to even further increase solar concentration. Furthermore, high concentrations of solar energy, as well as high optical efficiencies and power densities can be achieved by a TIR hybrid concentrator without using a secondary optics. Eliminating the need to bond a secondary optics to a solar cell reduces manufacturing and assembly costs and results in a simpler HCPV system that is lighter and less fragile with a less easily damaged solar cell. These performance benefits, in toto, translate into more efficient, more robust, and less costly HCPV systems than can be realized with Fresnel technology alone. Nevertheless, in some embodiments, a secondary optics can be used with a TIR hybrid concentrator to further increase performance for example, by spreading irradiance across a solar cell to reduce peak irradiance and/or allowing an increased aperture for a bigger spot size and increased acceptance angles of incident light.

At its optical center, a Fresnel lens is very efficient. As lens diameter increases, however, the spot size for the Fresnel lens increases, making it increasingly difficult to focus on a solar cell. Additionally, if a Fresnel lens has a large number of shallow teeth, each tooth is subject to more scattering losses created by the radii of the peak and valley of each feature. These losses are further compounded because the pitch of a Fresnel tooth decreases as a function of radius. At wider lens diameters, the image of the sun on a solar cell increases, and light spills off the edges of the solar cell. When the sun spot becomes greater than the solar cell, energy efficiency that can be recovered from a solar cell decreases dramatically, and the loss can be as great as 50%. Modern HCPV systems tend to use large Fresnel lenses, and can be, consequently, very lossy at low F-numbers. And, at an F-number less than N=1, a classic Fresnel lens stops working at acceptable levels for solar concentration.

In comparison, TIR-mediated spot size improves (i.e., spot size becomes smaller) as lens size increases, thus facilitating low F-numbers and high concentrations. TIR-mediated solar concentration offers little benefit over conventional Fresnel optics at F-numbers above N=1.2, but, significantly, becomes highly effective beginning at an F-number below N=1.0.

Very high concentrations (e.g., 2000 suns) can be achieved with embodiments of a system and method for a TIR hybrid concentrator as described herein. If TIR-mediated concentration is doubled (e.g., over a standard target concentration of 1000 suns), however, high irradiance levels are focused on the solar cell. An intense spot of power focused on the center of a current generation solar cell can generate too much current to be moved out of the solar cell, and can essentially destroy the center of the solar cell. Thus, as described herein, a TIR hybrid concentrator for the current generation of solar cells targets lower solar concentration than is maximally obtainable. As solar cell technology improves, however, a TIR hybrid concentrator as described herein can be used to generate higher solar concentrations, resulting in even more efficient and less costly HCPV systems.

Sizing of HCPV systems impacts manufacturing, shipping, and installation costs—as well as shadowing issues from neighboring HCPV trackers once HCPV modules are installed. Thus, power density (power per unit volume) can be an important comparison variable. One way to increase power density, and consequently decrease cost, is to decrease focal length. As discussed with respect to FIGS. 12, 14, 15, 16, and 17, standard Fresnel lenses require a greater focal length to achieve optical efficiencies that TIR hybrid concentrators generate at much shorter focal lengths. Standard Fresnel HCPV systems simply cannot concentrate to 1000 suns with a 120 mm focal length and 30 mm² solar cell. With a focal length of 120 mm, standard Fresnel optics can concentrate solar energy to, at best, 540 suns. To obtain a 1000 sun concentration, a standard Fresnel optics requires an F-number of N=1 with a focal length of at least 200 mm. Thus, TIR hybrid concentrators as described herein, which have high optical efficiencies at 120 mm, can be more cost-efficient than any standard Fresnel system currently available commercially.

The disclosed method and apparatus has been explained above with reference to several embodiments. Other embodiments will be apparent to those skilled in the art in light of this disclosure. Certain aspects of the described method and apparatus may readily be implemented using configurations other than those described in the embodiments above, or in conjunction with elements other than those described above. For example, different types of semiconductor cells—solar or otherwise—can be used in various embodiments described herein. It is expressly contemplated that multi-junction solar cells with more than 3 sub-cells can be used in various embodiments described herein. As another example, embodiments of the method and apparatus described herein are discussed with respect to target solar cells with an active area of 5.5 mm (“5.5 mm solar cells”) and target solar cells with an active area of 6.5 mm (“6.5 mm solar cells”), although it is expressly contemplated that these embodiments can be applied to solar cells of any size, including, for example, solar cells with widths of 1.2 cm to 1 mm.

Further, it should also be appreciated that the described apparatus and method can be implemented in numerous ways, including as an apparatus, a method, or a system. The methods described herein may be implemented by program instructions for instructing a processor to control machine tools to perform such methods. It should be noted that the order of the steps of the methods described herein may be altered and still be within the scope of the disclosure.

It is to be understood that the examples given are for illustrative purposes only and may be extended to other implementations and embodiments with different conventions and techniques. While a number of embodiments are described, there is no intent to limit the disclosure to the embodiment(s) disclosed herein. On the contrary, the intent is to cover all alternatives, modifications, and equivalents apparent to those familiar with the art.

In the foregoing specification, the invention is described with reference to specific embodiments thereof, but those skilled in the art will recognize that the invention is not limited thereto. Various features and aspects of the above-described invention may be used individually or jointly. Further, the invention can be utilized in any number of environments and applications beyond those described herein without departing from the broader spirit and scope of the specification. The specification and drawings are, accordingly, to be regarded as illustrative rather than restrictive. It will be recognized that the terms “comprising,” “including,” and “having,” as used herein, are specifically intended to be read as open-ended terms of art.

1. A hybrid optical concentrator for concentrating solar energy comprising a total internal reflection (TIR)-mediated concentrator region and a Fresnel-mediated concentrator region.

2. The hybrid optical concentrator of claim 1 wherein the TIR-mediated concentrator region comprises one or more features, each feature comprising:
(a) an entry surface through which a light ray passes from air into an optical medium of the feature;
(b) a reflector surface comprising a section angled such that an angle of incidence of the light ray traveling thereto from the entry surface is greater than a critical angle for the optical medium of the feature; and
(c) an emitting surface angled such that the light ray traveling thereto from the reflector surface exits the optical medium of the feature therethrough and is refracted at an angle that focuses the light ray onto a target solar cell.

3. The hybrid optical concentrator of claim 2 wherein each of the one or more features is annular.

4. The hybrid optical concentrator of claim 2 wherein each feature of the TIR-mediated concentrator region further comprises an undercut surface comprising an angled section, the angled section having a length determined by a slope of the emitting surface.

5. The hybrid optical concentrator of claim 1 wherein the Fresnel-mediated concentrator region comprises two or more teeth, the angle of each of the two or more teeth optimized to focus light to generate an acceptable spot size on a target solar cell.

6. The hybrid optical concentrator of claim 3 wherein the Fresnel-mediated concentrator region is positioned within an innermost annular feature of the one or more annular features of the TIR-mediated concentrator region.

7. The hybrid optical concentrator of claim 2 wherein geometric parameters of the reflector surface and the emitting surface of the one or more features are co-optimized to obtain a predetermined performance target.

8. The hybrid optical concentrator of claim 7 wherein the predetermined performance target is power output, power per unit area, power per unit volume, F-number, focal length, spot size, or solar concentration.

9. The hybrid optical concentrator of claim 8 wherein the predetermined performance target is a solar concentration greater than or equal to 500 suns.

10. The hybrid optical concentrator of claim 8 wherein the target solar cell size has an active area of less than 6.5 millimeters.

11. A TIR-mediated optical concentrator having one or more features, each feature comprising:
(a) an entry surface through which a light ray passes from air into an optical medium of the feature;
(b) a reflector surface comprising a section angled such that an angle of incidence of the light ray traveling thereto from the entry surface is greater than a critical angle for the optical medium of the feature; and
(c) an emitting surface angled such that the light ray traveling thereto from the reflector surface exits the optical medium of the feature therethrough and is refracted at an angle that focuses the light ray onto a target solar cell.

12. The TIR-mediated optical concentrator of claim 11 wherein each of the one or more features is annular.

13. The TIR-mediated optical concentrator of claim 11 wherein each feature of the TIR-mediated concentrator region further comprises an undercut surface comprising an angled section, the angled section having a length determined by a slope of the emitting surface.

14. The TIR-mediated optical concentrator of claim 11 wherein geometric parameters of the reflector surface and the emitting surface of the one or more features are co-optimized to obtain a predetermined performance target.

15. The TIR-mediated optical concentrator of claim 14 wherein the predetermined performance target is power output, power per unit area, power per unit volume, F-number, focal length, spot size, or solar concentration.

16. A method of making a hybrid optical concentrator for concentrating solar energy, the method comprising:
(a) designing a Fresnel-mediated concentrator region that encompasses a working range of a Fresnel optics;
(b) designing a total internal reflection (TIR)-mediated concentrator region having one or more designed features that encircle the Fresnel-mediated concentrator; and
(c) manufacturing the hybrid optical concentrator by injection molding the designed Fresnel-mediated concentrator region and the designed TIR-mediated concentrator region.

17. The method of claim 16 wherein designing the total internal reflection (TIR)-mediated concentrator region comprises:
(a) using a generic annular feature as a model, the generic feature comprising:
i. an entry surface through which a light ray passes from air into an optical medium of the feature;
ii. a reflector surface comprising a section angled such that an angle of incidence of the light ray traveling thereto from the entry surface is greater than a critical angle for the optical medium of the feature; and
iii. an emitting surface angled such that the light ray traveling thereto from the reflector surface exits the optical medium of the feature therethrough and is refracted at an angle that focuses the light ray onto a target solar cell;
(b) creating a designed feature from the model by modifying the emitting surface and the reflector surface of the model such that light exiting the designed feature through the emitting surface is focused to obtain an acceptable spot size on the target solar cell;
(c) modifying the emitting surface and the reflector surface of the designed feature to eliminate shadowing when the designed feature is shadowed by a previously designed feature;
(d) repeating steps (a), (b), and (c) to create another designed feature if a predetermined performance target has not been achieved; and
(e) applying a merit function to fine-tune a best solution for each of the one or more designed features such that the designed features together concentrate solar energy at a predetermined concentration on the target solar cell.

18. The method of claim 17 wherein the generic annular feature further comprises an undercut surface comprising an angled section, the angled section having a length determined by a slope of the emitting surface.

19. The method of claim 17 wherein modifying the emitting surface comprises modifying α, modifying θ₁, or modifying θ₃, wherein
α is defined as a slope of the emitting surface;
θ₁ is defined as an angle of refraction as the light ray exits the designed feature through the emitting surface; and
θ₃ is defined as an angle of incidence as the light ray travelling from the reflector surface strikes the emitting surface.

20. The method of claim 17 wherein modifying the reflector surface comprises changing an angle of the reflector surface such that light emitted from the designed feature is directed through the emitting surface to strike the target solar cell.

21. The method of claim 16 wherein designing the Fresnel-mediated concentrator region that encompasses a working range of a Fresnel optics comprises:
(a) modeling a first Fresnel tooth within the Fresnel working range, the first Fresnel tooth having a first angle which determines an angle of refraction of light exiting the first Fresnel tooth and a location within the Fresnel working range;
(b) modifying the first angle of the first Fresnel tooth to generate from light exiting the first Fresnel tooth a first lateral color spot of acceptable size on a target solar cell;
(c) modifying the location of the first Fresnel tooth to center the first lateral color spot of acceptable size on the target solar cell;
(d) modeling a next Fresnel tooth more medially within the Fresnel working range, the next Fresnel tooth having a next angle which determines an angle of refraction of light exiting the next Fresnel tooth;
(e) modifying the next angle of the next Fresnel tooth to position a next lateral color spot of acceptable size from light exiting the next Fresnel tooth on the target solar cell; and
(f) repeating steps (d) and (e) for another Fresnel tooth when the Fresnel working range is not complete.

22. The method of claim 16 wherein the injection molding is performed with silicone.

23. The method of claim 16 wherein the injection-molded Fresnel-mediated concentrator region and the injection-molded TIR-mediated concentrator region are bonded to a cover material to form the hybrid optical concentrator with a planar light entry surface.

24. The method of claim 16 further comprising the step of assembling the injection-molded Fresnel-mediated concentrator region and the injection-molded TIR-mediated concentrator region to form the hybrid optical concentrator with a planar light entry surface.
